(19) United States
(12) Patent Application Publication
(10) Pub. No.: US 2025/0301696 A1
(43) Pub. Date: Sep. 25, 2025

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventors: Nozomu NISHIURA, Kyoto-shi (JP); Kentaro NASU, Kyoto-shi (JP); Satoki TANIGUCHI, Kyoto-shi (JP); Kohei MORITA, Kyoto-shi (JP)

(73) Assignee: ROHM CO., LTD., Kyoto-shi (JP)

(21) Appl. No.: 19/080,969

(22) Filed: Mar. 17, 2025

(30) Foreign Application Priority Data
Mar. 21, 2024 (JP) 2024-045340

(51) Int. Cl. H10D 30/65; H10D 30/01; H10D 62/10; H10D 62/60; H10D 64/23; H10D 64/27; H10D 84/00

(52) U.S. Cl. CPC H10D 30/658; H10D 30/0289; H10D 30/655; H10D 62/127; H10D 62/60; H10D 64/257; H10D 64/513; H10D 84/153

(57) ABSTRACT

A semiconductor device includes a semiconductor chip including first and second main surfaces. A first semiconductor region of a first conductivity type is formed in the semiconductor chip near the first main surface. A second semiconductor region of a second conductivity type is formed closer to the second main surface than the first semiconductor region is. A trench structure includes a trench extending from the first main surface and partitioning the first semiconductor region into first and second regions. A control insulation film covers a wall of the trench. A control electrode is embedded in the trench with the control insulation film interposed to electrically connect the first and second regions. A third semiconductor region of the first conductivity type is formed closer to the second main surface than the second semiconductor region. The third semiconductor region and the trench structure sandwich the second semiconductor region.

### CROSS-REFERENCE TO RELATED APPLICATION

This application is based upon and claims the benefit of priority from Japanese Patent Application No. 2024-045340, filed on Mar. 21, 2024, the entire contents of which are incorporated herein by reference.

### BACKGROUND

### 1. Field

The following description relates to a semiconductor device and a method for manufacturing a semiconductor device.

International Patent Publication No. 2021/065740 discloses a semiconductor device including a semiconductor chip having a first main surface, an n-type drift layer formed in a portion of the semiconductor chip proximate to the first main surface, a trench gate structure formed in the first main surface in contact with the drift layer, a p-type channel region formed in the drift layer and covering side walls of the trench gate structure, and first and second source-drain regions formed in the drift layer at opposite sides of the channel region and spaced apart from each other near the side walls.

### BRIEF DESCRIPTION OF DRAWINGS

FIG. 1 is a circuit diagram of a semiconductor device in accordance with a first embodiment of the present disclosure.

FIG. 2 is a schematic perspective view of the semiconductor device in accordance with the first embodiment of the present disclosure.

FIG. 3 is a plan view of the semiconductor device illustrated in FIG. 2.

FIG. 4 is a plan view illustrating the internal structure of the semiconductor device shown in FIG. 2.

FIG. 5 is a plan view illustrating the internal structure of the semiconductor device shown in FIG. 2.

FIG. 6 is a plan view illustrating the internal structure of the semiconductor device shown in FIG. 2.

FIG. 7 is a plan view illustrating the internal structure of the semiconductor device shown in FIG. 2.

FIG. 8 is an enlarged view showing the section surrounded by double-dashed line VIII in FIG. 4.

FIG. 9 is a cross-sectional view taken along line IX-IX in FIG. 8.

FIG. 10 is a cross-sectional view taken along line X-X in FIG. 8.

FIG. 11 is a cross-sectional view taken along line XI-XI in FIG. 8.

FIG. 12 is a cross-sectional view taken along line XII-XII in FIG. 8.

FIG. 13A is a diagram illustrating a step in a process for manufacturing the semiconductor device in accordance with a first embodiment of the present disclosure.

FIG. 13B is a diagram illustrating a step following the step of FIG. 13A.

FIG. 13C is a diagram illustrating a step following the step of FIG. 13B.

FIG. 13D is a diagram illustrating a step following the step of FIG. 13C.

FIG. 13E is a diagram illustrating a step following the step of FIG. 13D.

FIG. 13F is a diagram illustrating a step following the step of FIG. 13E.

FIG. 13G is a diagram illustrating a step following the step of FIG. 13F.

FIG. 13H is a diagram illustrating a step following the step of FIG. 13G.

FIG. 13I is a diagram illustrating a step following the step of FIG. 13H.

FIG. 13J is a diagram illustrating a step following the step of FIG. 13I.

FIG. 14 is a cross-sectional view illustrating a current path of the semiconductor device in accordance with the first embodiment of the present disclosure.

FIG. 15 is a plan view illustrating the current path of the semiconductor device in accordance with the first embodiment of the present disclosure.

FIG. 16 is a cross-sectional view illustrating a first modified example of the semiconductor device in accordance with the first embodiment of the present disclosure.

FIG. 17 is a cross-sectional view illustrating a second modified example of the semiconductor device in accordance with the first embodiment of the present disclosure.

FIG. 18 is a cross-sectional view illustrating a third modified example of the semiconductor device in accordance with the first embodiment of the present disclosure.

FIG. 19 is a schematic plan view illustrating the internal structure of a semiconductor device in accordance with a second embodiment of the present disclosure.

FIG. 20 is an enlarged view showing the part surrounded by double-dashed line XX in FIG. 19.

FIG. 21 is an enlarged view showing the part surrounded by double-dashed line XX in FIG. 19.

FIG. 22 is a cross-sectional view taken along line XXII-XXII in FIG. 20.

FIG. 23 is a cross-sectional view taken along line XXIII-XXIII in FIG. 20.

FIG. 24 is a cross-sectional view taken along line XXIV-XXIV in FIG. 20.

FIG. 25 is a cross-sectional view illustrating a current path of the semiconductor device in accordance with the second embodiment of the present disclosure.

FIG. 26 is a plan view illustrating the current path of the semiconductor device in accordance with the second embodiment of the present disclosure.

FIG. 27 is a plan view illustrating a modified example of the semiconductor device in accordance with the second embodiment of the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### First Embodiment

### Structure of Semiconductor Device 1A

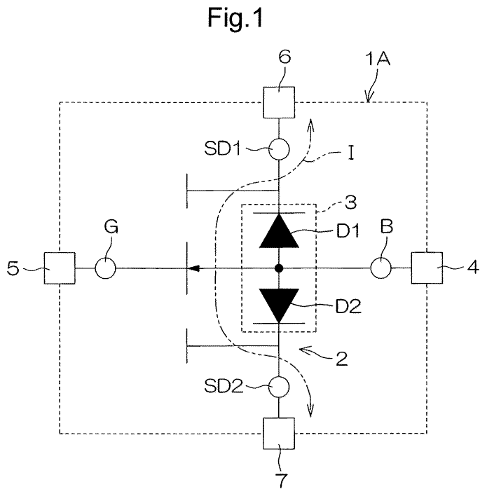

FIG. 1 is a circuit diagram of a semiconductor device 1A in accordance with a first embodiment of the present disclosure.

The semiconductor device 1A includes a metal insulator semiconductor field effect transistor (MISFET) 2 of a common source-drain type. The MISFET 2 includes a base B, a gate G, a first source-drain SD1, and a second source-drain SD2. The first source-drain SD1 and the second source-drain SD2 each have the functionalities of a source and a drain. Depending on the connection layout of the semiconductor device 1A, the first source-drain SD1 may function as a source, and the second source-drain SD2 may function as a drain. Further, the first source-drain SD1 may function as a drain, and the second source-drain SD2 may function as a source.

Reference voltage (e.g., ground voltage) is applied to the base B. Gate voltage VG, which references the base B, is applied to the gate G. The gate G controls electrical connection and interruption of the flow of current I between the first source-drain SD1 and the second source-drain SD2. First source-drain voltage VSD1 (first voltage) is applied to the first source-drain SD1. Second source-drain voltage VSD2 (second voltage), which differs from the first source-drain voltage VSD1, is applied to the second source-drain SD2.

The semiconductor device 1A further includes a diode pair 3 connected to the first source-drain SD1 and the second source-drain SD2. The diode pair 3 restricts (interrupts) the current I flowing between the first source-drain SD1 and the second source-drain SD2 when the MISFET 2 is in an off state.

The diode pair 3 includes a first body diode D1 and a second body diode D2 that are connected in reverse bias. The first body diode D1 and the second body diode D2 each include an anode and a cathode.

The anode of the first body diode D1 is connected to the base B. The cathode of the first body diode D1 is connected to the first source-drain SD1. The anode of the second body diode D2 is connected to the base B. The cathode of the second body diode D2 is connected to the second source-drain SD2.

The semiconductor device 1A is a four-terminal device including four external terminals 4, 5, 6, and 7. The external terminals 4 to 7 are, specifically, a base terminal 4, a gate terminal 5, a first source-drain terminal 6, and a second source-drain terminal 7. The base terminal 4 is connected to the base B. The gate terminal 5 is connected to the gate G. The first source-drain terminal 6 is connected to the first source-drain SD1. The second source-drain terminal 7 is connected to the second source-drain SD2.

The MISFET 2 is a bidirectional device that allows current I to flow in two directions, that is, toward the first source-drain terminal 6 and toward the second source-drain terminal 7. More specifically, when the first source-drain terminal 6 is connected to the high-voltage side (input side), the second source-drain terminal 7 is connected to the low-voltage side (output side). When the first source-drain terminal 6 is connected to the low-voltage side (output side), the second source-drain terminal 7 is connected to the high-voltage side (input side).

When the gate voltage VG applied to the gate terminal 5 is greater than or equal to a gate threshold voltage Vth (Vth≤VG), current I flows between the first source-drain terminal 6 and the second source-drain terminal 7. When the gate voltage VG applied to the gate terminal 5 is less than the gate threshold voltage Vth (VG<Vth), current does not flow between the first source-drain terminal 6 and the second source-drain terminal 7. The on-off of the MISFET 2 is controlled in this manner.

With the semiconductor device 1A, the single MISFET 2 implements the functionality of a circuit connecting the drains of two MISFETs that are not of the common source-drain type. Thus, the semiconductor device 1A allows the on resistance to be decreased by shortening the current path. The structure of the semiconductor device 1A will now be described in detail.

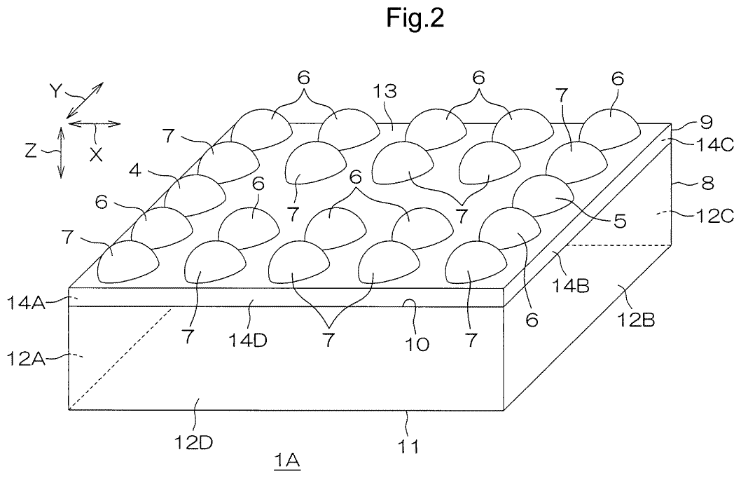

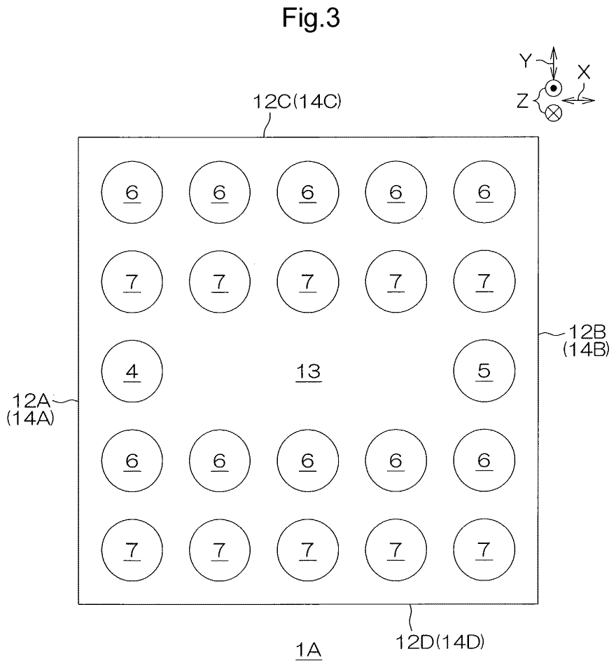

FIG. 2 is a schematic perspective view of the semiconductor device 1A in accordance with the first embodiment of the present disclosure. FIG. 3 is a plan view of the semiconductor device 1A illustrated in FIG. 2. An example in which the semiconductor device 1A is formed by a chip size package, in which the size of the chip is the size of the package, will now be described.

With reference to FIGS. 2 and 3, the semiconductor device 1A has a laminate structure including a semiconductor chip 8 and an insulation layer 9.

The semiconductor chip 8 has the form of a rectangular parallelepiped. The semiconductor chip 8 includes a first main surface 10, an opposite second main surface 11, and side surfaces 12A, 12B, 12C, and 12D connecting the first main surface 10 and the second main surface 11. The side surfaces 12A to 12D are, specifically, a first side surface 12A, a second side surface 12B, a third side surface 12C, and a fourth side surface 12D.

The insulation layer 9 is formed on the first main surface 10. The insulation layer 9 includes an insulation main surface 13 and the insulation side surfaces 14A, 14B, 14C, and 14D. The insulation side surfaces 14A to 14D are, specifically, a first insulation side surface 14A, a second insulation side surface 14B, a third insulation side surface 14C, and a fourth insulation side surface 14D. The insulation side surfaces 14A to 14D extend from the edges of the insulation main surface 13 toward the semiconductor chip 8 and are continuous with the side surfaces 12A to 12D. The insulation side surfaces 14A to 14D are flush with the side surfaces 12A to 12D, respectively.

The external terminals 4 to 7 are formed on the insulation main surface 13. In this embodiment, the external terminals 4 to 7 are arranged at intervals in a first direction X and a second direction Y, forming a matrix of five rows and five columns.

The base terminal 4 is located in the third row, first column. The gate terminal 5 is located in the third row, fifth column. The gate terminal 5 faces the base terminal 4 in the first direction X. The first source-drain terminals 6 are located in the first row, first to fifth columns, and in the fourth row, first to fifth columns. The second source-drain terminals 7 are located in the second row, first to fifth columns, and in the fifth row, first to fifth columns.

The second source-drain terminals 7 in the second row face the first source-drain terminal 6 in the first row in the second direction Y with a one-to-one relationship. The second source-drain terminals 7 in the fifth row face the first source-drain terminal 6 in the fourth row in the second direction Y with a one-to-one relationship.

In this embodiment, the third row, second to fourth columns are open spaces. Any one of the base terminal 4, the gate terminal 5, the first source-drain terminal 6, and the second source-drain terminal 7 may be arranged in each open space. An open terminal in an electrically floating state may be arranged in each open space. The base terminal 4, the gate terminal 5, the first source-drain terminals 6, and the second source-drain terminals 7 are not limited to the arrangement illustrated in FIGS. 2 and 3 and may be in any number and any layout.

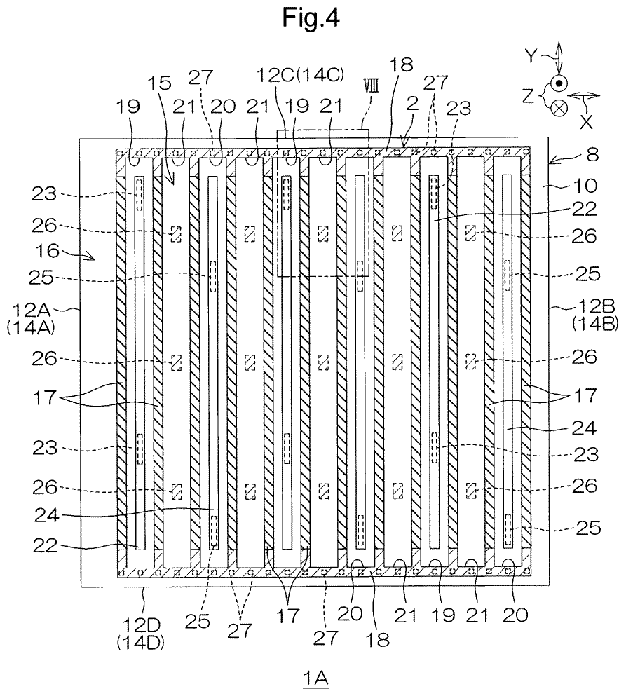

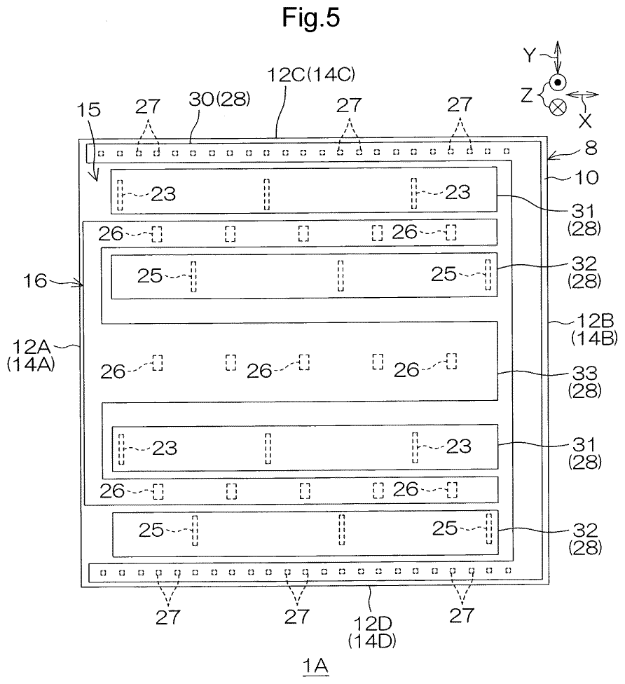

FIGS. 4 to 7 are plan views illustrating the internal structure of the semiconductor device 1A shown in FIG. 2. FIG. 4 is a plan view of the semiconductor chip 8, and FIGS. 5 to 7 show the wiring patterns inside the insulation layer 9.

Referring to FIGS. 4 to 7, the first main surface 10 of the semiconductor chip 8 includes an active region 15 and a peripheral region 16 surrounding the active region 15.

The peripheral region 16 may have a closed shape and extend along the side surfaces 12A to 12D of the semiconductor chip 8. The peripheral region 16 may be a region having a closed shape and extending a few micrometers inward from the side surfaces 12A to 12D of the semiconductor chip 8. The active region 15 may be a central region of the semiconductor chip 8 surrounded by the peripheral region 16. The active region 15, for example, occupies most of the element structure of the MISFET 2. The term “closed shape” as used in this specification may refer to any looped shape, a shape that is endless and continuous, or a shape that is generally looped and has a gap like the letter character “C”,

Referring to FIG. 4, the element structure of the MISFET 2 is formed in the active region 15. In this embodiment, the element structure is a metal insulator semiconductor field effect transistor (MISFET) of a trench gate-lateral type.

The MISFET 2 includes trench structures formed in the first main surface 10, namely, first trench structures 17 and trench connection structures 18.

Each first trench structure 17 may be referred to as “the trench gate structure.” The first trench structures 17 are formed within the first main surface 10 and separated from the edges of the first main surface 10. The first trench structures 17 are arranged at intervals in the first direction X and have the form of strips extending in the second direction Y. The first trench structures 17 are arranged in a striped pattern extending in the second direction Y in plan view. Each first trench structure 17 in the second direction Y includes a first end at one side and a second end at the other side.

The trench connection structures 18 are connected to the first trench structures 17. Among the multiple (two in this embodiment) trench connection structures 18, the trench connection structure 18 at the side of the third side surface 12C connects the first ends of the first trench structures 17, and the trench connection structure 18 at the side of the fourth side surface 12D connects the second ends of the first trench structures 17.

The trench connection structures 18 are formed within the first main surface 10 separated from the edges of the first main surface 10. The trench connection structures 18 have the form of strips extending in the first direction X, which intersect the direction in which the first trench structures 17 extend, and are connected to the first ends and the second ends of the first trench structures 17. This forms regions in the first main surface 10 that are each surrounded and closed by two of the first trench structures 17 and the two trench connection structures 18.

Closed regions 19 to 21 are each sandwiched by the first trench structures 17 in the first direction X and each have the form of a strip extending in the second direction Y. The closed regions 19 to 21 are arranged next to one another and spaced apart from one another by the first trench structures 17 to form a striped pattern in their entirety. The closed regions 19 to 21 may be first source-drain regions 19, second source-drain regions 20, and drift regions 21.

In this embodiment, a first source-drain region 19 opposes a second source-drain region 20 with a drift region 21 interposed. A first trench structure 17 is formed between a first source-drain region 19 and a drift region 21 and between a drift region 21 and a second source-drain region 20.

The first source-drain regions 19 and the second source-drain regions 20 are alternately arranged at intervals in the first direction X so that the drift regions 21 are sandwiched between adjacent ones of the first source-drain regions 19 and the second source-drain regions 20. Sets of the first source-drain region 19, the drift region 21, the second source-drain region 20, and the drift region 21 in order from the left side as viewed in FIG. 4 are arranged repetitively in the first direction X.

Each first source-drain region 19 includes a first contact region 22. The first contact region 22 may be referred to as “the first source-drain contact region.” In this embodiment, the first contact region 22 has the form of a strip extending in the second direction Y within the first source-drain region 19. The edges of the first contact region 22 are arranged to define a closed shape and are separated inwardly from the first trench structures 17 and the trench connection structures 18.

First lower contacts 23 are formed in the first contact region 22. Each first lower contact 23 may be referred to as “the first source-drain contact.” In this embodiment, the first lower contacts 23 are formed at an interval in the second direction Y. Each first lower contact 23 is rectangular in plan view and longer in the second direction Y. Each first contact region 22 may include only one first lower contact 23.

Each second source-drain region 20 includes a second contact region 24. The second contact region 24 may be referred to as “the second source-drain contact region.” In this embodiment, the second contact region 24 has the form of a strip extending in the second direction Y within the second source-drain region 20. The edges of the second contact region 24 are arranged to define a closed shape and are separated inwardly from the first trench structures 17 and the trench connection structures 18.

Second lower contacts 25 are formed in the second contact region 24. Each second lower contact 25 may be referred to as “the second source-drain contact.” In this embodiment, the second lower contacts 25 are formed at an interval in the second direction Y. Each second lower contact 25 is rectangular in plan view and longer in the second direction Y. Each second contact region 24 may include only one second lower contact 25.

First base contacts 26 are formed in each drift region 21. In this embodiment, the first base contacts 26 are formed at intervals in the second direction Y. Each first base contact 26 is rectangular in plan view and longer in the second direction Y. Each drift region 21 may include only one first base contact 26.

In this embodiment, the first lower contacts 23, the second lower contacts 25, and the first base contacts 26 are electrically insulated from one another and fixed at different potentials. The first lower contacts 23, the second lower contacts 25 and the first base contacts 26 are arranged discretely on the first main surface 10. In this embodiment, the first lower contacts 23, the second lower contacts 25 and the first base contacts 26 are arranged so that contacts of the same type (same potential) are arranged at regular intervals in the first direction X.

As viewed in FIG. 4, a row of the first lower contacts 23 aligned in the first direction X, a row of the first base contacts 26 aligned in the first direction X, and a row of the second lower contacts 25 aligned in the first direction X are formed in order from the upper side. Thus, the first lower contacts 23, the second lower contacts 25, and the first base contacts 26 are arranged so that contacts of different types do not face each other in the first direction X.

First gate contacts 27 are formed in the trench connection structures 18. In this embodiment, the first gate contacts 27 are arranged at intervals in the first direction X. The first gate contacts 27 may be arranged at intersections of the trench connection structures 18 and the first trench structures 17. The first gate contacts 27 may be positioned to face at least one of the first source-drain regions 19, the second source-drain regions 20, and the drift regions 21 in the second direction Y.

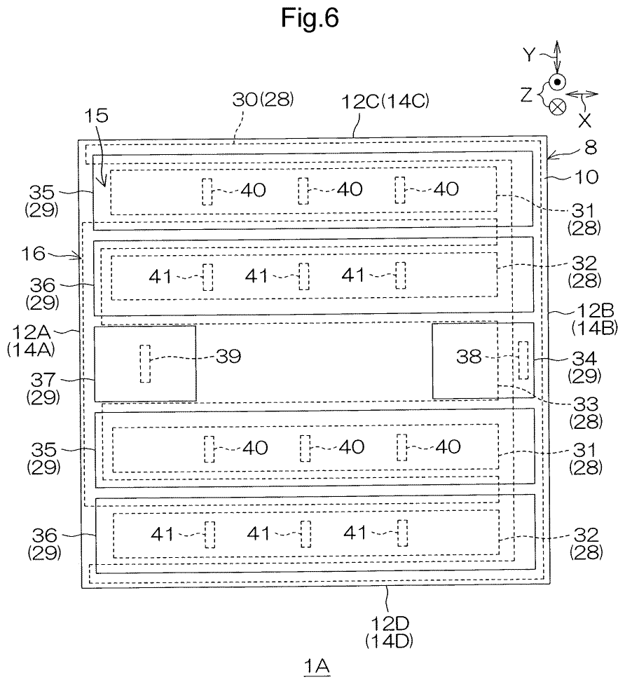

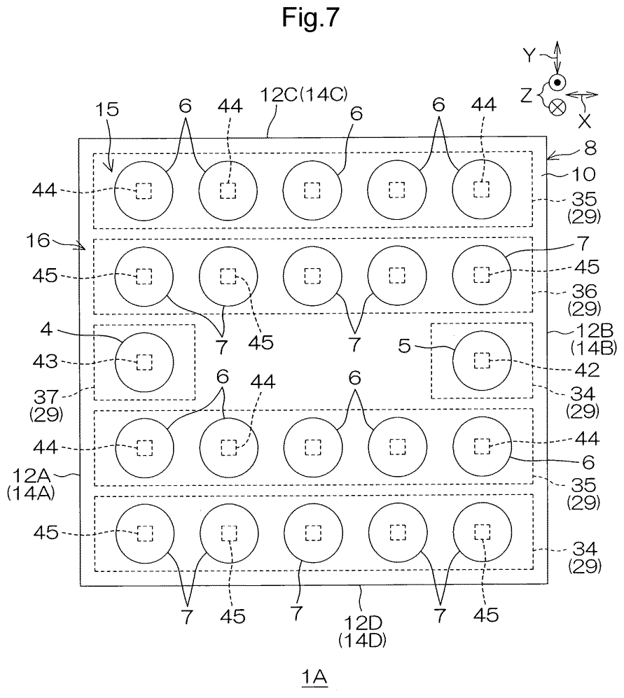

Referring to FIGS. 5 to 7, wiring layers are formed on the first main surface 10 of the semiconductor chip 8, and external terminals are connected to the uppermost one of the wiring layers. The wiring layers form a multi-layer wiring structure and include, for example, a first wiring layer 28, which is depicted by solid lines in FIG. 5, and a second wiring layer 29, which is depicted by solid lines in FIG. 6, in order from the first main surface 10 toward the upper side. As shown in FIG. 7, in this embodiment, the external terminals are connected to the second wiring layer 29.

The first wiring layer 28 may be referred to as “the first metal.” Referring to FIG. 5, the first wiring layer 28 includes a first gate wiring layer 30, first lower wiring layers 31, second lower wiring layers 32, and a first base wiring layer 33. The first gate wiring layer 30, the first lower wiring layers 31, the second lower wiring layers 32, and the first base wiring layer 33 are physically independent from one another. Each first lower wiring layer 31 may be referred to as “the first lower source-drain wiring layer.” Each second lower wiring layer 32 may be referred to as “the second lower source-drain wiring layer.”

The first gate wiring layer 30 is formed along the peripheral region 16 of the semiconductor chip 8. The first gate wiring layer 30 is shaped to surround the active region 15. For example, the first gate wiring layer 30 is shaped to surround the active region 15 from three sides and be open toward one of the side surfaces 12A to 12D of the semiconductor chip 8 (in FIG. 5, toward first side surface 12A). The first gate wiring layer 30 includes three straight portions extending along the peripheral region 16. Among the three straight portions, the two straight portions facing each other in the second direction Y cover the first gate contacts 27 and are connected to the first gate contacts 27.

The first lower wiring layers 31 are formed covering the first lower contacts 23 and are connected to the first lower contacts 23. In this embodiment, the first lower wiring layers 31 have the form of strips extending in the first direction X to cover all of the first lower contacts 23 aligned straight in the first direction X.

The second lower wiring layers 32 are formed covering the second lower contacts 25 and are connected to the second lower contacts 25. In this embodiment, the second lower wiring layers 32 have the form of strips extending in the first direction X to cover all of the second lower contacts 25 aligned straight in the first direction X.

The first lower wiring layers 31 and the second lower wiring layers 32 are alternately arranged at intervals in the second direction Y. In this embodiment, two strips of the first lower wiring layers 31, which are spaced apart from each other, and two strips of the second lower wiring layers 32, which are spaced apart from each other, form a striped pattern.

The first base wiring layer 33 is formed covering the first base contacts 26 and connected to the first base contacts 26. In this embodiment, the first base wiring layer 33 includes strips extending in the first direction X to cover all of the first base contacts 26 aligned in the first direction X. In this embodiment, each strip of the first base wiring layer 33 is arranged in regions between each first lower wiring layer 31 and the adjacent second lower wiring layer 32. The strips of the first base wiring layer 33 are all connected at the open side of the first gate wiring layer 30 (i.e., toward first side surface 12A).

The second wiring layer 29 may be referred to as “the second metal.” Referring to FIG. 6, the second wiring layer 29 includes a second gate wiring layer 34, first upper wiring layers 35, second upper wiring layers 36, and a second base wiring layer 37. The second gate wiring layer 34, the first upper wiring layers 35, the second upper wiring layers 36, and the second base wiring layer 37 are physically independent from one another. Each first upper wiring layer 35 may be referred to as “the first upper source drain wiring layer.” Each second upper wiring layer 36 may be referred to as “the second upper source drain wiring layer.” In FIG. 6, the first wiring layer 28 is depicted in broken lines to show the relationship of the second wiring layer 29 and the first wiring layer 28.

The second gate wiring layer 34 and the second base wiring layer 37 are each rectangular in plan view. The second gate wiring layer 34 and the second base wiring layer 37 are formed in a central portion of the semiconductor chip 8 with respect to the second direction Y and face each other in the first direction X. In this embodiment, among the side surfaces 12A to 12D of the semiconductor chip 8, the second gate wiring layer 34 is located proximate to the second side surface 12B, and the second base wiring layer 37 is located proximate to the first side surface 12A at the opposite side. The second gate wiring layer 34 is connected to the first gate wiring layer 30 by a second gate contact 38. The second base wiring layer 37 is connected to the first base wiring layer 33 by a second base contact 39.

The first upper wiring layers 35 have the form of strips extending along the first lower wiring layers 31 and covering the first lower wiring layers 31. The first upper wiring layers 35 are connected to the first lower wiring layers 31 by first upper contacts 40. The first upper contacts 40 may be arranged at intervals in the first direction X.

The second upper wiring layers 36 have the form of strips extending along the second lower wiring layers 32 and covering the second lower wiring layers 32. The second upper wiring layers 36 are connected to the second lower wiring layers 32 by second upper contacts 41. The second upper contacts 41 may be arranged at intervals in the first direction X.

Referring to FIG. 7, the external terminals are arranged on corresponding ones of the second wiring layers 29. In FIG. 7, the second wiring layers 29 are depicted in broken lines to show the relationship of the external terminals and the second wiring layers 29.

The gate terminal 5 is arranged on the second gate wiring layer 34 and connected to the second gate wiring layer 34 by a gate terminal contact 42. The base terminal 4 is arranged on the second base wiring layer 37 and connected to the second base wiring layer 37 by a base terminal contact 43.

The first source-drain terminals 6 are arranged on the strip-like first upper wiring layers 35 at intervals in the longitudinal direction. Each first source-drain terminal 6 is connected to the corresponding first upper wiring layer 35 by a first terminal contact 44.

The second source-drain terminals 7 are arranged on the strip-like second upper wiring layers 36 at intervals in the longitudinal direction. Each second source-drain terminal 7 is connected to the corresponding second upper wiring layer 36 by a second terminal contact 45.

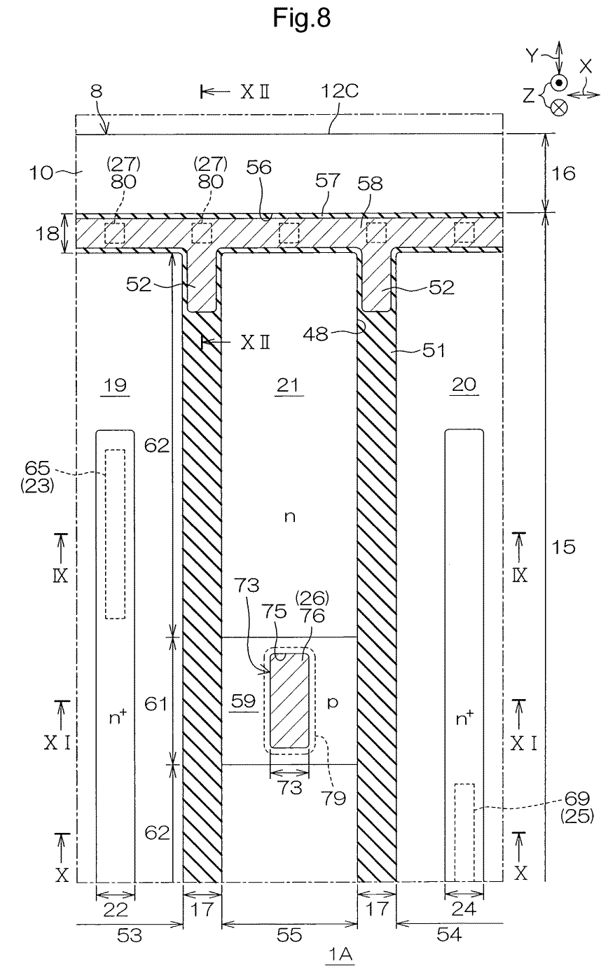

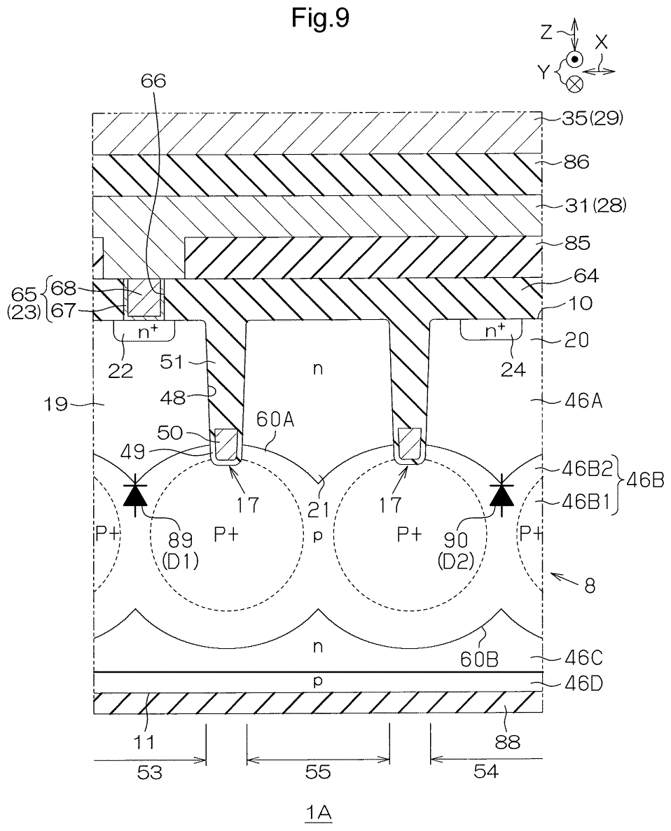

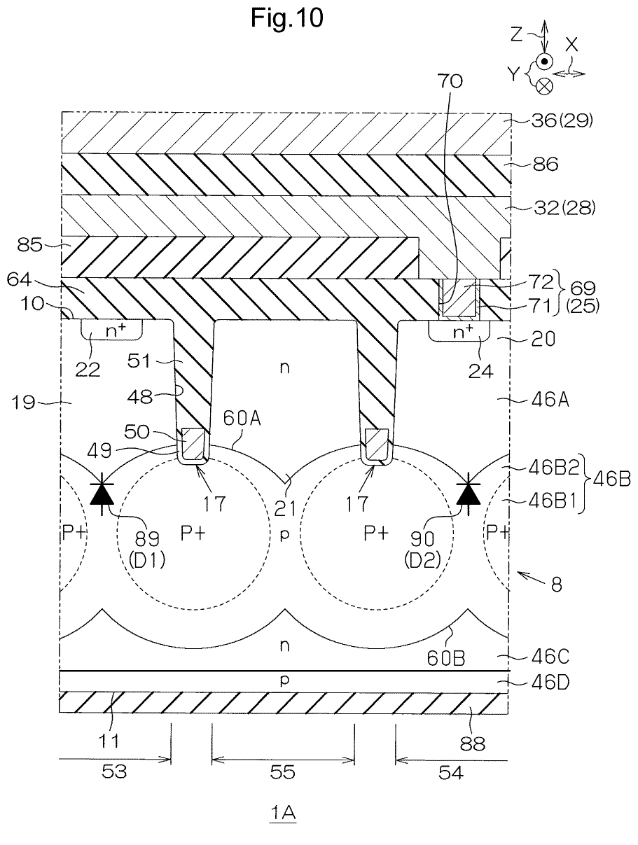

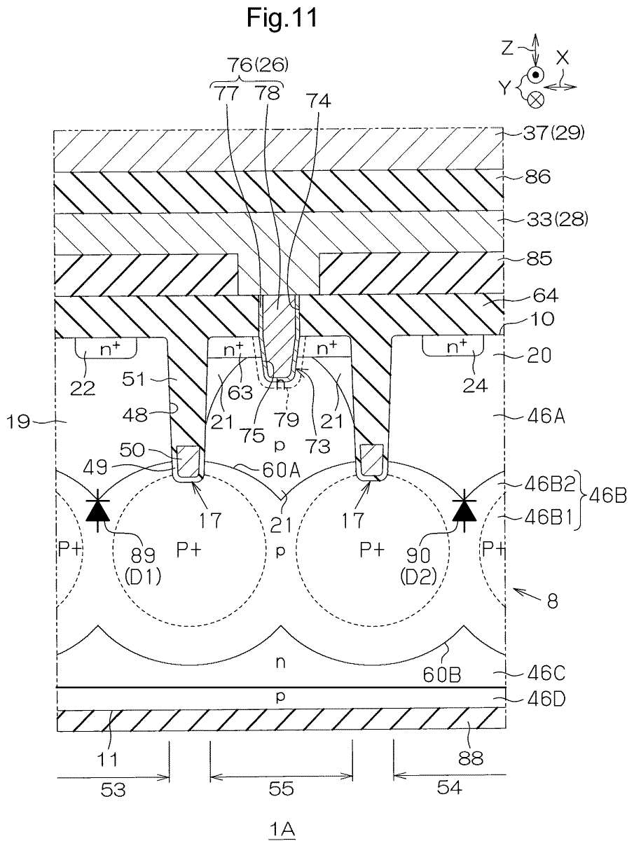

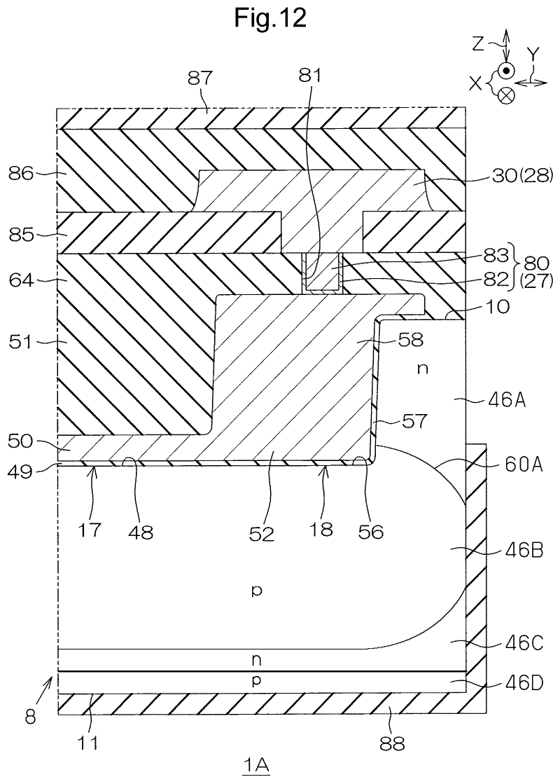

FIG. 8 is an enlarged view showing the part surrounded by double-dashed line VIII in FIG. 4. FIG. 9 is a cross-sectional view taken along line IX-IX in FIG. 8. FIG. 10 is a cross-sectional view taken along line X-X in FIG. 8. FIG. 11 is a cross-sectional view taken along line XI-XI in FIG. 8. FIG. 12 is a cross-sectional view taken along line XII-XII in FIG. 8.

Referring to FIGS. 9 to 12, the semiconductor device 1A includes the semiconductor chip 8. The semiconductor chip 8 is, for example, a monolayer semiconductor chip. The monolayer semiconductor chip 8 is a single-structure semiconductor substrate that does not have an epitaxial layer. In this embodiment, the semiconductor chip 8 includes silicon (Si) or wide bandgap semiconductor monocrystals which do not have an epitaxial layer. A wideband semiconductor has a wider bandgap than a Si bandgap. The semiconductor chip 8 may be a Si chip or a silicon carbide (SiC) chip.

The semiconductor device 1A includes a first semiconductor region 46A of an n-type (first conductivity type) formed in the semiconductor chip 8 at a region near the first main surface 10. The first semiconductor region 46A may be referred to as “the drift layer.” The first semiconductor region 46A is formed in the semiconductor chip 8 spaced apart from the second main surface 11 and located near the first main surface 10. The first semiconductor region 46A, which has the form of a layer, is located proximate to the first main surface 10 and extends along the first main surface 10 entirely exposed from the first main surface 10 and partially exposed from the first to fourth side surfaces 12A to 12D.

The first semiconductor region 46A may be spaced apart from the first to fourth side surfaces 12A to 12D and formed inward from the first main surface 10. The first semiconductor region 46A may have an n-type impurity concentration in a range from 1×10¹⁴ cm⁻³ to 1×10¹⁸ cm⁻³, inclusive. The n-type impurity concentration of the first semiconductor region 46A may be uniform or varied. In one example, the n-type impurity concentration of the first semiconductor region 46A decreases from the first main surface 10 toward the second main surface 11. In this case, the n-type impurity concentration may be, for example, an average concentration.

The semiconductor device 1A includes a second semiconductor region 46B of a p-type (second conductivity type) that is formed in the semiconductor chip 8 and is closer to the second main surface 11 than the first semiconductor region 46A is. The p-type impurity concentration of the second semiconductor region 46B will be described later.

The second semiconductor region 46B is formed in the semiconductor chip 8 spaced apart from the second main surface 11 toward the first main surface 10. The second semiconductor region 46B, which has the form of a layer, extends in the semiconductor chip 8 along the first main surface 10 (first semiconductor region 46A) and is partially exposed from the first to fourth side surfaces 12A to 12D. The second semiconductor region 46B is electrically connected to the first semiconductor region 46A in the semiconductor chip 8. More specifically, the second semiconductor region 46B forms a pn junction with the first semiconductor region 46A.

The semiconductor device 1A includes a third semiconductor region 46C of the n-type (first conductivity type) that is formed in the semiconductor chip 8 and is closer to the second main surface 11 than the second semiconductor region 46B is. In other words, the third semiconductor region 46C is located between the second semiconductor region 46B and the second main surface 11 in the thickness direction of the semiconductor chip 8. The third semiconductor region 46C may have an n-type impurity concentration in a range from 1×10¹⁴ cm⁻³ to 1×10¹⁸ cm⁻³, inclusive. In one example, the n-type impurity concentration of the third semiconductor region 46C is less than the n-type impurity concentration of the first semiconductor region 46A. In this case, the n-type impurity concentration may be, for example, an average concentration.

The third semiconductor region 46C, which has the form of a layer, extends along the first main surface 10 (second semiconductor region 46B) and is partially exposed from the first to fourth side surfaces 12A to 12D. The third semiconductor region 46C is electrically connected to the second semiconductor region 46B in the semiconductor chip 8.

Accordingly, the semiconductor device 1A includes, in the thickness direction of the semiconductor chip 8, the first semiconductor region 46A of the n-type (first conductivity type) that is formed near the first main surface 10, the second semiconductor region 46B of the p-type (second conductivity type) that is formed closer to the second main surface 11 than the first semiconductor region 46A is, and the third semiconductor region 46C of the n-type (first conductivity type) that is formed closer to the second main surface 11 than the second semiconductor region 46B is. The second semiconductor region 46B electrically insulates the first semiconductor region 46A and the third semiconductor region 46C. The first semiconductor region 46A, the second semiconductor region 46B, and the third semiconductor region 46C will be described later in detail.

The semiconductor device 1A includes a fourth semiconductor region 46D of the p-type (second conductivity type) that is formed in the semiconductor chip 8 closer to the second main surface 11 than the third semiconductor region 46C is. The fourth semiconductor region 46D may be referred to as “the base layer.” The fourth semiconductor region 46D may have a p-type impurity concentration in a range from 1×10¹³ cm⁻³ to 1×10¹⁶ cm⁻³, inclusive.

The first trench structures 17 extend through the first semiconductor region 46A to the second semiconductor region 46B. In this embodiment, each first trench structure 17 includes a bottom wall located in the second semiconductor region 46B. The first trench structures 17 are each configured to control the reversion and non-reversion of a channel (described later as channel 96) in the second semiconductor region 46B.

The first trench structures 17 may be arranged at intervals (pitch) in a range from 0.02 μm to 20 μm, inclusive (preferably, in a range from 0.2 μm to 5 μm, inclusive). Preferably, the first trench structures 17 are arranged at equal intervals in the first direction X. The first trench structures 17 may each have a width in the first direction X in a range from 0.01 μm to 10 μm, inclusive (preferably, in a range from 0.1 μm to 0.5 μm, inclusive). The first trench structures 17 may each have a depth in a range from 0.2 μm to 30 μm, inclusive (preferably, in a range from 0.5 μm to 10 μm, inclusive).

The internal structure of one of the first trench structures 17 will now be described. The first trench structure 17 includes a first trench 48, a gate insulation film 49 (control insulation film), a gate electrode 50 (control electrode), and an embedded insulator 51.

The first trench 48 may be referred to as “the gate trench.” The first trench 48 is formed in the first main surface 10 and defined by the wall surfaces (side walls and bottom wall) of the first trench structure 17. The first semiconductor region 46A and the second semiconductor region 46B are exposed from the wall surfaces of the first trench 48.

The first trench 48 may be tapered so that its width narrows from the first main surface 10 toward the bottom side in a cross-sectional view. The first trench 48 may extend at a right angle from the first main surface 10. The first trench 48 may have curved bottom corners. The bottom wall of the first trench 48 may be entirely curved toward the second main surface 11.

The gate insulation film 49 covers the side walls and bottom wall of the first trench 48. In this embodiment, the gate insulation film 49 covers the side walls and bottom wall of the first trench 48 and defines a recess space near the bottom wall of the first trench 48. The gate insulation film 49 may have a thickness in a range from 5 nm to 1000 nm, inclusive, in a direction normal to the wall surface of the first trench 48. The gate insulation film 49 may be at least one of a silicon oxide film, a silicon nitride film, an aluminum oxide film, a zirconium oxide film, a hafnium oxide film, and a tantalum oxide film. Preferably, the gate insulation film 49 is formed by a silicon oxide film. In particular, the gate insulation film 49 is preferably formed by an oxide (thermally oxidized film) of the semiconductor chip 8.

The gate electrode 50 is embedded in the first trench 48 with the gate insulation film 49 interposed. More specifically, the gate electrode 50, which is embedded in the recess space defined by the gate insulation film 49 near the bottom wall of the first trench 48, opposes the second semiconductor region 46B and the third semiconductor region 46C with the gate insulation film 49 interposed. The gate electrode 50 extends across a boundary 60A of the first semiconductor region 46A and the second semiconductor region 46B in a depth direction of the first trench 48.

Referring to FIGS. 8 and 12, the gate electrode 50 includes extensions 52 extending from the bottom side toward the open side of the first trench 48. There may be any number of extensions 52. In this embodiment, there are two extensions 52 spaced part in the second direction Y. In this embodiment, the two extensions 52 are respectively formed at the two ends of the first trench 48. The extensions 52 each extend in the second direction Y in plan view.

An open side recess is defined between each extension 52 and the wall surface of the corresponding first trench 48 at the open side of the first trench 48. The open side recess has the form of a slit extending in the second direction Y. The extension 52 may extend upward from the first main surface 10. The extension 52 may extend out of the first trench 48 over the first main surface 10 with part of the gate insulation film 49 interposed. The extensions 52 may be located closer to the bottom of the first trench 48 than to the first main surface 10.

The gate electrode 50 may include at least one of a metal conductor and a non-metal conductor. The gate electrode 50 may include at least one of tungsten, aluminum, copper, an aluminum alloy, a copper alloy, and a conductive polysilicon. Preferably, the gate electrode 50 includes a non-metal conductor (conductive polysilicon). The conductive polysilicon may be a p-type polysilicon or an n-type polysilicon. Preferably, the conductive polysilicon is an n-type polysilicon.

The embedded insulator 51 is embedded in the first trench 48 at the open side of the first trench 48 and covers the gate electrode 50. More specifically, the embedded insulator 51 is embedded in the open side recess defined by the gate electrode 50. The embedded insulator 51 corresponds to a field insulator that reduces the electric field at the first trench 48. The area of the embedded insulator 51 facing the first semiconductor region 46A is greater than the area of the gate electrode 50 facing the second semiconductor region 46B.

The embedded insulator 51 has a greater thickness in the depth direction of the first trench 48 than the gate electrode 50. The embedded insulator 51 may be at least one of a silicon oxide film, a silicon nitride film, an aluminum oxide film, a zirconium oxide film, a hafnium oxide film, and a tantalum oxide film. Preferably, the embedded insulator 51 is formed by a silicon oxide film. Preferably, the embedded insulator 51 is formed from the same material as the gate insulation film 49. In this case, preferably, the embedded insulator 51 is formed by an insulative vapor deposition film and has a density that differs from that of the gate insulation film 49.

Referring to FIGS. 8 to 11, the semiconductor device 1A includes mesas 53 to 55 defined by the first trench structures 17 in the first main surface 10 (first semiconductor region 46A). The mesas 53 to 55 are strips, each extending in the second direction Y between two adjacent ones of the first trench structures 17. The mesas 53 to 55 include first mesas 53, second mesas 54, and drift mesas 55.

Each first mesa 53 is distanced in the first direction X from the adjacent second mesa 54 with a drift mesa 55 interposed. The first mesas 53 are formed in the first source-drain regions 19 and may each be referred to as “the first source-drain mesa.” The second mesas 54 are formed in the second source-drain regions 20 and may each be referred to as “the second source-drain mesa.” The drift mesas 55 form the drift regions 21.

Referring to FIGS. 8 and 12, the trench connection structures 18 extend through the first semiconductor region 46A to the second semiconductor region 46B. The trench connection structures 18 and the first trench structures 17 define the mesas 53 to 55 (first mesas 53, second mesas 54, and drift mesas 55).

The trench connection structures 18 may each have a width in the second direction Y in a range from 0.01 μm to 10 μm, inclusive (preferably, in range from 0.1 μm to 2 μm, inclusive). The width of each trench connection structure 18 may be substantially equal to that of each first trench structure 17. The trench connection structure 18 may each have a depth in a range from 0.2 μm to 30 μm, inclusive (preferably, in a range from 0.5 μm to 10 μm, inclusive). The depth of each trench connection structure 18 may be substantially equal to that of each first trench structure 17.

Each trench connection structure 18 includes a connection trench 56, a connection insulation film 57, and a connection electrode 58. The connection trench 56, formed in the first main surface 10, is connected to the first trenches 48 and defined by the wall surfaces (side walls and bottom wall) of the trench connection structure 18. The wall surfaces (side walls and bottom wall) of each trench connection structure 18 is continuous with the wall surfaces (side walls and bottom wall) of the corresponding first trenches 48. The first semiconductor region 46A and the second semiconductor region 46B are exposed from the wall surfaces of the connection trench 56.

The connection trench 56 may be tapered so that its width narrows from the first main surface 10 toward the bottom side in a cross-sectional view. The connection trench 56 may extend at a right angle from the first main surface 10. The connection trench 56 may have curved bottom corners. The bottom wall of the connection trench 56 may be entirely curved toward the second main surface 11.

The connection insulation film 57 covers the side walls and the bottom wall of the connection trench 56. In this embodiment, the connection insulation film 57 covers the side walls and the bottom wall at the open side and the bottom side of the connection trench 56 and defines a recess space in the connection trench 56. The connection insulation film 57 is continuous with the gate insulation film 49 in each first trench 48.

The connection insulation film 57 may have a thickness in a range from 5 nm to 1000 nm, inclusive. Preferably, the connection insulation film 57 has substantially the same thickness as the gate insulation film 49. The connection insulation film 57 may be at least one of a silicon oxide film, a silicon nitride film, an aluminum oxide film, a zirconium oxide film, a hafnium oxide film, and a tantalum oxide film. Preferably, the connection insulation film 57 is formed from the same material as the gate insulation layer.

The connection electrode 58, which is embedded in the connection trench 56 with the connection insulation film 57 interposed, opposes the first semiconductor region 46A and the second semiconductor region 46B. The connection electrode 58 is continuous with the gate electrodes 50 in the first trenches 48. More specifically, the connection electrode 58 is continuous with the extensions 52. This fixes the connection electrode 58 at the same potential as the gate electrodes 50.

The portions of the connection electrode 58 that are continuous with the extensions 52 may be elements of the connection electrode 58 or elements of the gate electrodes 50. The connection electrode 58 has an upper end that is closer to the first main surface 10 than the upper ends of the gate electrodes 50 are. The connection electrode 58 may project upward from the first main surface 10. The connection electrode 58 may extend out of the connection trench 56 over the first main surface 10 with part of the connection insulation film 57 interposed. The connection electrode 58 may be located closer to the bottom of the connection trench 56 than to the first main surface 10.

The connection electrode 58 may include at least one of a metal conductor and a non-metal conductor. The connection electrode 58 may include at least one of tungsten, aluminum, copper, an aluminum alloy, a copper alloy, and a conductive polysilicon. Preferably, the connection electrode 58 is formed from the same material as the gate electrode 50.

In each first mesa 53, the first source-drain region 19 is formed by the first semiconductor region 46A. The first contact region 22 is formed in an outer portion of the first source-drain region 19. The first contact region 22 has a higher n-type impurity concentration than the first semiconductor region 46A. The n-type impurity concentration of the first contact region 22 may be in a range from 1×10¹⁸ cm⁻³ to 1×10²¹ cm⁻³, inclusive (in this embodiment, approximately, 1×10¹⁹ cm⁻³).

Preferably, the first contact region 22 is formed in the central part of the corresponding first mesa 53 in plan view. The first contact region 22 is shorter in length in the second direction Y than the first trench structures 17, and located inward from the two ends of each of the first trench structures 17. Each of the two ends of the first contact region 22 opposes the corresponding trench connection structure 18 with part of the first semiconductor region 46A interposed in the second direction Y.

The first contact region 22 extends in a transverse direction (second direction Y) parallel to the first main surface 10 in a cross-sectional view. More specifically, the first contact region 22 is formed at a position located toward the first main surface 10 from the upper end of the gate electrode 50. The first contact region 22 opposes the embedded insulator 51 with part of the first semiconductor region 46A interposed in a transverse direction parallel to the first main surface 10. The first contact region 22 is separated from the upper end of the gate electrode 50 toward the first main surface 10, and does not face the gate electrode 50 in a transverse direction parallel to the first main surface 10. This reduces the electric field applied to the first trench structures 17.

The first contact region 22 may have a thickness in a range from 10 nm to 150 nm, inclusive (preferably, in a range from 50 nm to 100 nm, inclusive). Preferably, the first contact region 22 is spaced apart from the upper end of the gate electrode 50 in the thickness direction (normal direction Z) of the semiconductor chip 8 by a distance in a range from 0.1 μm to 2 μm, inclusive (preferably, in a range from 0.5 μm to 1.5 μm, inclusive).

In each second mesa 54, the second source-drain region 20 is formed by the first semiconductor region 46A. The second contact region 24 is formed in an outer portion of the second source-drain region 20. The second contact region 24 has a higher n-type impurity concentration than the first semiconductor region 46A. The n-type impurity concentration of the second contact region 24 may be in a range from 1×10¹⁸ cm⁻³ to 1×10²¹ cm⁻³, inclusive (in this embodiment, approximately 1×10¹⁹ cm⁻³).

Preferably, the second contact region 24 is formed in the central part of the second mesa 54 in plan view. The second contact region 24 is shorter in length in the second direction Y than each first trench structure 17, and located inward from the two ends of each first trench structure 17. Each of the two ends of the second contact region 24 opposes the corresponding trench connection structure 18 with part of the first semiconductor region 46A interposed in the second direction Y.

The second contact region 24 extends in a transverse direction (second direction Y) parallel to the first main surface 10 in a cross-sectional view. More specifically, the second contact region 24 is formed at a position located toward the first main surface 10 from the upper end of the gate electrode 50. The second contact region 24 opposes the embedded insulator 51 with part of the first semiconductor region 46A interposed in a transverse direction parallel to the first main surface 10. The second contact region 24 is separated from the upper end of the gate electrode 50 toward the first main surface 10, and does not face the gate electrode 50 in a transverse direction parallel to the first main surface 10. This reduces the electric field applied to the first trench structures 17.

The second contact region 24 has a thickness in a range from 10 nm to 150 nm, inclusive (preferably, in a range from 50 nm to 100 nm, inclusive). Preferably, the second contact region 24 is spaced apart from the upper end of the gate electrode 50 in the thickness direction (normal direction Z) of the semiconductor chip 8 by a distance in a range from 0.1 μm to 2 μm, inclusive (preferably, in a range from 0.5 μm to 1.5 μm, inclusive).

Referring to FIGS. 8 and 11, each drift mesa 55 includes a p-type projection 59 projecting selectively from the second semiconductor region 46B into the first semiconductor region 46A toward the first main surface 10. Referring to FIG. 11, the projection 59 may extend upward in a parabolic manner from the boundary 60A of the first semiconductor region 46A and the second semiconductor region 46B, and include a peak in the vicinity of the first main surface 10. In this embodiment, the peak of the projection 59 is separated from the first main surface 10 toward the second main surface 11. Parts of the drift region 21 may be formed at opposite sides of the projection 59 in the first direction X. Such parts of the drift regions 21 are sandwiched between the projection 59 and the adjacent first trench structure 17.

Referring to FIG. 8, the projection 59 is selectively formed in the drift mesa 55 in the second direction Y. In this embodiment, multiple projections 59 are arranged at intervals in the second direction Y. Each projection 59 extends from one first trench structure 17 to an adjacent first trench structure 17 in the first direction X. Thus, the projection 59 separates the drift region 21 at a number of locations in the second direction Y. The p-type impurity concentration of the projection 59 may be in a range from 1×10¹⁶ cm⁻³ to 1×10²² cm⁻³ (in this embodiment, approximately, 1×10¹⁹ cm⁻³).

Referring to FIG. 8, in the second direction Y, the projections 59 define contact regions 61 and current regions 62 in the corresponding drift regions 21. Each contact region 61 is where the projection 59 is formed in plan view. Each current region 62, which does not include the projection 59 in plan view, is formed by the first semiconductor region 46A (drift region 21) from the boundary 60A to the first main surface 10.

In the second direction Y, the contact regions 61 may be shorter than the current regions 62. For example, each contact region 61 may have a length in the second direction Y that is in a range from 0.1 μm to 100 μm, inclusive, and each current region 62 may have a length in the second direction Y in a range from 1 μm to 3000 μm, inclusive.

Each drift mesa 55 further includes a first impurity region 63. FIG. 8 does not show the first impurity region 63. Among the contact regions 61 and the current regions 62, the first impurity region 63 is selectively formed in the contact regions 61. The first impurity region 63 is formed proximate to the first main surface 10 and in contact with the peak of each projection 59. The first impurity region 63 has a higher n-type impurity concentration than the first semiconductor region 46A. The n-type impurity concentration of the first impurity region 63 may be in a range from 1×10¹⁵ cm⁻³ to 1×10²⁰ cm⁻³ (in this embodiment, approximately 1×10¹⁸ cm⁻³).

The semiconductor device 1A includes a main surface insulation film 64 that selectively covers the first main surface 10. The main surface insulation film 64 may be part of the insulation layer 9. The main surface insulation film 64 covers the first trench structures 17 and the trench connection structures 18 on the first main surface 10. In this embodiment, the main surface insulation film 64 entirely covers the first main surface 10 and is continuous with the first to fourth side surfaces 12A to 12D.

The main surface insulation film 64 may have a thickness in a range from 0.1 μm to 2 μm, inclusive. Preferably, the main surface insulation film 64 has a greater thickness than the gate insulation film 49. The main surface insulation film 64 may be at least one of a silicon oxide film, a silicon nitride film, an aluminum oxide film, a zirconium oxide film, a hafnium oxide film, and a tantalum oxide film. Preferably, the main surface insulation film 64 is formed by a silicon oxide film.

In this embodiment, the main surface insulation film 64 is formed from the same material as the embedded insulator 51 and formed integrally with the embedded insulator 51. Thus, the main surface insulation film 64 extends from above the first main surface 10 into the first trenches 48 to form the embedded insulators 51. In other words, the main surface insulation film 64 is formed by integrating parts of the embedded insulators 51 projecting out of the first trenches 48 as films on the first main surface 10.

Referring to FIGS. 8 and 9, the semiconductor device 1A includes first electrodes 65 electrically connected to the first semiconductor region 46A in the first mesas 53. In this embodiment, the first electrodes 65 correspond to “the first lower contacts 23.” The first electrodes 65 extend through the main surface insulation film 64 and are connected to the first mesas 53. More specifically, the first electrodes 65 are arranged in first connection openings 66, which are formed in the main surface insulation film 64.

The first electrodes 65 are formed from metal. In this embodiment, each first electrode 65 has a laminate structure including a first barrier film 67 and a first electrode body 68. The first barrier film 67 is formed along the wall of the corresponding first connection opening 66. The first barrier film 67 may be formed by a titanium-based metal film. The first barrier film 67 may have a monolayer structure or a laminate structure including one or both of a titanium film and a titanium nitride film.

The first electrode body 68 is embedded in the first connection opening 66 with the first barrier film 67 interposed and electrically connected to the corresponding first mesa 53 (first contact region 22) through the first barrier film 67. The first electrode body 68 may include at least one of tungsten, aluminum, copper, an aluminum alloy, and a copper alloy. In this embodiment, the first electrode body 68 includes tungsten. The first electrode 65 does not have to include the first barrier film 67 and may include only the first electrode body 68.

Referring to FIGS. 8 and 10, the semiconductor device 1A includes second electrodes 69 electrically connected to the first semiconductor region 46A in the second mesas 54. In this embodiment, the second electrodes 69 correspond to “the second lower contacts 25.” The second electrodes 69 extend through the main surface insulation film 64 and are connected to the second mesas 54. More specifically, the second electrodes 69 are arranged in second connection openings 70, which are formed in the main surface insulation film 64.

The second electrodes 69 are formed from metal. In this embodiment, each second electrode 69 has a laminate structure including a second barrier film 71 and a second electrode body 72. The second barrier film 71 is formed along the wall of the corresponding second connection opening 70. The second barrier film 71 may be formed by a titanium-based metal film. The second barrier film 71 may have a monolayer structure or a laminate structure including one or both of a titanium film and a titanium nitride film.

The second electrode body 72 is embedded in the second connection opening 70 with the second barrier film 71 interposed and electrically connected to the corresponding second mesa 54 (second contact region 24) through the second barrier film 71. The second electrode body 72 may include at least one of tungsten, aluminum, copper, an aluminum alloy, and a copper alloy. In this embodiment, the second electrode body 72 includes tungsten. The second electrode 69 does not have to include the second barrier film 71 and may include only the second electrode body 72.

Referring to FIGS. 8 and 11, the semiconductor device 1A includes second trench structures 73 formed in the first main surface 10 at the drift mesas 55.

In this embodiment, the second trench structures 73 extend through the main surface insulation film 64 and are formed in the corresponding drift mesas 55. More specifically, the second trench structures 73 extend through base connection openings 74 in the main surface insulation film 64 and are formed in the drift mesas 55. Referring to FIG. 8, the second trench structures 73 are selectively formed in the contact regions 61 and not formed in the current regions 62.

Referring to FIG. 11, each second trench structure 73 extends to the corresponding projection 59. In this embodiment, the second trench structures 73 are shallower than the first trench structures 17. More specifically, each second trench structure 73 extends through the first impurity region 63 to the corresponding projection 59. The second trench structure 73 has a bottom wall located in the projection 59.

The distance from the second trench structure 73 to the adjacent first trench structure 17 may be in a range from 0.01 μm to 10 μm, inclusive (preferably, in a range from 0.1 μm to 0.5 μm, inclusive). Each second trench structure 73 may have a width in the first direction X in a range from 0.01 μm to 10 μm, inclusive (preferably, in a range from 0.1 μm to 0.5 μm, inclusive). The width of each of the second trench structures 73 may be greater than or equal to the width of each of the first trench structures 17 or less than the width of each of the first trench structures 17. The second trench structures 73 may each have a depth in a range from 0.1 μm to 10 μm, inclusive (preferably, in a range from 0.2 μm to 0.5 μm, inclusive). Such a depth allows for the formation of a silicide layer 79 (described later) in the entire second trench structure 73.

Each second trench structure 73 includes a base trench 75 and a base electrode 76. In this embodiment, each base electrode 76 corresponds to “the first base contact 26.”

The base trench 75, which extends through the main surface insulation film 64, is formed in the first main surface 10 and defined by the wall surfaces (side walls and bottom wall) of the second trench structure 73. In this embodiment, the base trench 75 includes the base connection opening 74, which is formed in the main surface insulation film 64. More specifically, the base trench 75 extends through the main surface insulation film 64 and the first impurity region 63 to the projection 59. The first impurity region 63 and the projection 59 are exposed from the wall surfaces of the base trench 75.

The base trench 75 may be tapered so that its width narrows from the first main surface 10 toward the bottom side in a cross-sectional view. The base trench 75 may extend at a right angle from the first main surface 10. The base trench 75 may have curved bottom corners. The bottom wall of the base trench 75 may be entirely curved toward the second main surface 11.

The base electrode 76 is embedded in the base trench 75 without an insulation film. In the base trench 75, the base electrode 76 is mechanically and electrically connected to the first impurity region 63 and the projection 59, and mechanically connected to the main surface insulation film 64. In the base trench 75, the base electrode 76 includes a part extending from the first main surface 10 into the semiconductor chip 8 and a part extending from the first main surface 10 into the main surface insulation film 64. Thus, the base electrode 76 has an upper end projecting upward from the first main surface 10. Further, the upper end of the base electrode 76 is located upward from the upper end of the gate electrode 50 (upper end of each extension 52).

The base electrode 76 may include at least one of a metal conductor and a non-metal conductor. Preferably, the base electrode 76 and the gate electrode 50 are formed from different conductive materials. Preferably, the base electrode 76 includes a metal. In this embodiment, the base electrode 76 has a laminate structure including a base barrier film 77 and a base electrode body 78.

The base barrier film 77 is formed along the side walls and the bottom wall of the base trench 75, and covers the first impurity region 63, the projection 59, and the main surface insulation film 64 in the base trench 75. The base barrier film 77 defines a recess space in the base trench 75. The base barrier film 77 may be formed by a titanium-based metal film. The base barrier film 77 may have a monolayer structure or a laminate structure including one or both of a titanium film and a titanium nitride film. Preferably, the base barrier film 77 is formed from the same material as the first barrier film 67 and the second barrier film 71.

The base electrode body 78 is embedded in the base trench 75 with the base barrier film 77 interposed, and covers the first impurity region 63, the projection 59, and the main surface insulation film 64 with the base barrier film 77 interposed. The base electrode body 78 is electrically connected to the first impurity region 63 and the projection 59 by the base barrier film 77. The base electrode body 78 may include at least one of tungsten, aluminum, copper, an aluminum alloy, and a copper alloy. Preferably, the base electrode body 78 is formed from the same material as the first electrode body 68 and the second electrode body 72. In this embodiment, the base electrode body 78 includes tungsten. The base electrode 76 does not have to include the base barrier film 77, and may include only the base electrode body 78.

The silicide layer 79 is formed on the wall of the base trench 75. The silicide layer 79 is formed entirely on the side walls and bottom wall of the base trench 75 at the boundary of the semiconductor chip 8 and the base barrier film 77. The silicide layer 79 may extend vertically across the boundary of the first impurity region 63 and the projection 59 in the thickness direction of the semiconductor chip 8.

As long as the silicide layer 79 is formed entirely on the side walls and the bottom wall of the base trench 75, the wall smoothness of the base trench 75 can be improved thereby allowing for satisfactory contact between the base electrode body 78 and the base trench 75. This reduces the contact resistance of the base electrode body 78. As a result, the potential at the second semiconductor region 46B may be fixed at a predetermined potential by forming the second trench structures 73 only in the contact regions 61 and not in the current regions 62.

Referring to FIGS. 8 and 12, the semiconductor device 1A includes third electrodes 80 electrically connected to the first trench structures 17. The third electrodes 80 each correspond to “the first gate contact 27.” The third electrodes 80 extend through the main surface insulation film 64 and are connected to either one of or both of the first trench structures 17 (extensions 52) and the trench connection structures 18 (connection electrode 58).

More specifically, the third electrodes 80 are arranged in third connection openings 81, which are formed in the main surface insulation film 64. In this embodiment, the third electrodes 80 are mechanically and electrically connected to the trench connection structures 18. That is, the third electrodes 80 are electrically connected to the first trench structures 17 by the trench connection structures 18.

Referring to FIG. 8, in this embodiment, the third electrodes 80 are arranged at intervals along the trench connection structures 18 in plan view. The third electrodes 80 may have any shape in plan view. The third electrodes 80 may be circular or quadrilateral in plan view. The third electrodes 80 may each have the form of a strip extending along the corresponding trench connection structure 18 in plan view.

The third electrodes 80 are formed from metal. In this embodiment, each third electrode 80 has a laminate structure including a third barrier film 82 and a third electrode body 83. The third barrier film 82 is formed along the wall of the corresponding third connection opening 81. The third barrier film 82 may be formed by a titanium-based metal film. The third barrier film 82 may have a monolayer structure or a laminate structure including one or both of a titanium film and a titanium nitride film. Preferably, the third barrier film 82 is formed from the same material as the first barrier film 67, the second barrier film 71, and the base barrier film 77.

The third electrode body 83 is embedded in the third connection opening 81 with the third barrier film 82 interposed and electrically connected to the extensions 52 (connection electrode 58) by the third barrier film 82. The third electrode body 83 may include at least one of tungsten, aluminum, copper, an aluminum alloy, and a copper alloy. Preferably, the third electrode body 83 is formed from the same material as the first electrode body 68. In this embodiment, the third electrode body 83 includes tungsten. The third electrode 80 does not have to include the third barrier film 82 and may include only the third electrode body 83.

Detail Structure of First Semiconductor Region 46A, Second Semiconductor Region 46B, and Third Semiconductor Region 46C

Referring to FIGS. 9 to 12, the first semiconductor region 46A, the second semiconductor region 46B, and the third semiconductor region 46C will now be described. The third semiconductor region 46C, which is located close to the second main surface 11, and the trench structures 17 sandwich the second semiconductor region 46B. The second semiconductor region 46B covers the bottom wall and the side walls of each first trench structure 17 at the lower end of the first trench structure 17. The second semiconductor region 46B opposes the gate electrode 50 with the gate insulation film 49 interposed at the bottom wall of each first trench structure 17.

The second semiconductor region 46B is shaped so that its thickness varies in the X-direction. More specifically, the second semiconductor region 46B is thick at portions overlapping the bottom wall of each first trench structure 17 (also referred to hereafter as the trench distal end) and gradually thins as the trench distal end becomes farther. The second semiconductor region 46B has the form of circles arranged next to one another in the X-direction, with adjacent circles partially overlapping each other. The center of each circle is located immediately below a trench distal end. In this case, the thickness of the second semiconductor region 46B is maximal at parts located immediately below each trench distal end and is minimal at parts where adjacent circles overlap each other (also referred to as constrictions hereafter). In this case, the boundary 60A between the first semiconductor region 46A and the second semiconductor region 46B and the boundary 60B between the second semiconductor region 46B and the third semiconductor region 46C are shaped by connecting arcs that are arranged next to each other in the X-direction between adjacent ones of the first trench structures 17.

The first semiconductor region 46A may have an average thickness in a range from 0.2 μm to 40 μm, inclusive (preferably, in a range from 0.5 μm to 10 μm, inclusive).

In the Z-direction, the distance from the first main surface 10 to a point where the boundary 60A intersects the side wall of a first trench structure 17 is referred to as the first thickness of the first semiconductor region 46A. The first thickness of the first semiconductor region 46A may be in a range from 0.2 μm to 30 μm, inclusive (preferably, in a range from 0.5 μm to 10 μm, inclusive).

In the Z-direction, the distance from the first main surface 10 to a point where the distal end of a constriction in the second semiconductor region 46B intersects the boundary 60A is referred to as the second thickness of the first semiconductor region 46A. The second thickness of the first semiconductor region 46A may be in a range from 0.2 μm to 40 μm, inclusive (preferably, in a range from 0.5 μm to 10 μm, inclusive). Preferably, the second thickness of the first semiconductor region 46A is greater than the first thickness of the first semiconductor region 46A.

The first semiconductor region 46A has a thickness immediately below at least one of the first contact region 22 and the second contact region 24 that is referred to as the third thickness of the first semiconductor region 46A. The third thickness of the first semiconductor region 46A may be in a range from 0.2 μm to 40 μm, inclusive (preferably, in a range from 0.5 μm to 10 μm, inclusive). The third thickness of the first semiconductor region 46A is greater than the first thickness of the first semiconductor region 46A.

The second semiconductor region 46B may have an average thickness in a range from 0.01 μm to 10 μm, inclusive (preferably, in a range from 0.1 μm to 1 μm, inclusive).

The second semiconductor region 46B has a thickness immediately below a trench distal end that is referred to as the first thickness of the second semiconductor region 46B. The first thickness of the second semiconductor region 46B may be in a range from 0.01 μm to 10 μm, inclusive (preferably, in a range from 0.1 μm to 1 μm, inclusive).

The second semiconductor region 46B has a thickness at a constriction that is referred to as the second thickness of the second semiconductor region 46B. The second thickness of the second semiconductor region 46B may be in a range from 0.01 μm to 10 μm, inclusive (preferably, in a range from 0.01 μm to 1 μm, inclusive). Preferably, the second thickness of the second semiconductor region 46B is less than the first thickness of the second semiconductor region 46B.

The second semiconductor region 46B has a thickness immediately below at least one of the first contact region 22 and the second contact region 24 that is referred to as the third thickness of the second semiconductor region 46B. The third thickness of the second semiconductor region 46B may be in a range from 0.01 μm to 10 μm, inclusive (preferably, in a range from 0.01 μm to 1 μm, inclusive).

The third semiconductor region 46C has a thickness immediately below a trench distal end that is referred to as the first thickness of the third semiconductor region 46C. The first thickness of the third semiconductor region 46C may be 0.001 μm or greater (preferably, 0.01 μm or greater).

In the Z-direction, the distance from the fourth semiconductor region 46D to a point where the distal end of a constriction in the second semiconductor region 46B intersects the boundary 60B is referred to as the second thickness of the third semiconductor region 46C. The second thickness of the third semiconductor region 46C may be 0.001 μm or greater (preferably, 0.01 μm or greater). Preferably, the second thickness of the third semiconductor region 46C is greater than the first thickness of the third semiconductor region 46C.

The third semiconductor region 46C has a thickness immediately below at least one of the first contact region 22 and the second contact region 24 that is referred to as the third thickness of the third semiconductor region 46C. The third thickness of the third semiconductor region 46C may be 0.001 μm or greater (preferably, 0.01 μm or greater). Preferably, the third thickness of the third semiconductor region 46C is greater than the first thickness of the third semiconductor region 46C.

The second semiconductor region 46B includes high-concentration regions 46B1, each having a high p-type impurity concentration, and low-concentration regions 46B2, each having a lower p-type impurity concentration than the high-concentration regions 46B1. Each high-concentration region 46B1 in the second semiconductor region 46B is a circular region of which the center is located immediately below a trench distal end in a cross-sectional view. The high-concentration region 46B1 is formed in correspondence with each trench distal end. Each low-concentration region 46B2 entirely surrounds a corresponding one of the high-concentration regions 46B1 in a cross-sectional view.

In the second semiconductor region 46B of one example, adjacent high-concentration regions 46B1 in the X-direction are separated from each other, and the low-concentration regions 46B2 are formed between adjacent high-concentration regions 46B1. Adjacent high-concentration regions 46B 1 in the X-direction may be connected to each other. Further, the second semiconductor region 46B may include a part where adjacent high-concentration regions 46B 1 in the X-direction are connected to each other and a part where adjacent high-concentration regions 46B1 in the X-direction are not connected to each other.

The p-type impurity concentration of the high-concentration regions 46B1 may be 1×10¹⁰ cm⁻³ to 2×10¹⁸ cm⁻³, inclusive (in this embodiment, approximately 1×10¹⁵ cm⁻³). The p-type impurity concentration of the low-concentration region 46B2 may be 0.5×10¹⁰ cm⁻³ to 1×10¹⁸ cm⁻³, inclusive (in this embodiment, approximately 1×10¹⁴ cm⁻³). The high-concentration regions 46B1 and the low-concentration regions 46B2 are each formed so that, for example, the p-type impurity concentration gradually decreases as its center, which is located immediately below the corresponding trench distal end, becomes farther.

Referring to FIG. 9, the first source-drain regions 19, the second source-drain regions 20, and the drift regions 21 are arranged with the first trench structures 17 interposed in the X-direction (first direction). In one example, the drift regions 21 (drift mesas 55) are shorter in length in the X-direction (first direction length) than the first source-drain regions 19 (first mesas 53). The drift regions 21 (drift mesas 55) are shorter in length in the X-direction (first direction length) than the second source-drain regions 20 (second mesas 54).

In this case, the X-direction length of the drift regions 21 (drift mesas 55) may be in a range from 0.01 μm to 3 μm, inclusive (preferably, in a range from 0.01 μm to 0.5 μm, inclusive). The X-direction length of the first source-drain regions 19 (first mesas 53) may be in a range from 0.1 μm to 3 μm, inclusive (preferably, in a range from 0.1 μm to 0.5 μm, inclusive). The X-direction length of the second source-drain regions 20 (second mesas 54) may be in a range from 0.1 μm to 3 μm, inclusive (preferably, in a range from 0.1 μm to 0.5 μm, inclusive).

Referring to FIGS. 9 to 12, the semiconductor device 1A includes a first interlayer insulation film 85 formed on the main surface insulation film 64. The first interlayer insulation film 85 may be part of the insulation layer 9. The first interlayer insulation film 85 may include at least one of silicon oxide and silicon nitride. The first interlayer insulation film 85 entirely covers the main surface insulation film 64 and is continuous with the first to fourth side surfaces 12A to 12D. The first interlayer insulation film 85 may include a flat surface extending along the first main surface 10. The flat surface of the first interlayer insulation film 85 may have polishing marks.

The first wiring layer 28 is formed on the first interlayer insulation film 85. The first wiring layer 28 may include at least one of titanium, tungsten, aluminum, copper, an aluminum alloy, a copper alloy, and a conductive polysilicon. The first wiring layer 28 may include at least one of a Cu film (Cu film having purity of 99% or greater), a pure Al film (Al film having purity of 99% or greater), an AlCu alloy film, an AlSi alloy film, and an AlSiCu alloy film.

As described above, the first wiring layer 28 includes the first gate wiring layer 30, the first lower wiring layers 31, the second lower wiring layers 32, and the first base wiring layer 33. The first gate wiring layer 30 is connected to the first gate contacts 27 (FIG. 12), and the first lower wiring layers 31 are connected to the first lower contacts 23 (FIG. 9). The second lower wiring layers 32 are connected to the second lower contacts 25 (FIG. 10), and the first base wiring layer 33 is connected to the first base contacts 26 (FIG. 11).

Referring to FIGS. 9 to 12, the semiconductor device 1A includes a second interlayer insulation film 86 formed on the first interlayer insulation film 85 to cover the first wiring layer 28. The second interlayer insulation film 86 may be part of the insulation layer 9. The second interlayer insulation film 86 may include at least one of silicon oxide and silicon nitride. The second interlayer insulation film 86 entirely covers the first interlayer insulation film 85 and is continuous with the first to fourth side surfaces 12A to 12D. The second interlayer insulation film 86 may include a flat surface extending along the first main surface 10. The flat surface of the second interlayer insulation film 86 may have polishing marks.

The second wiring layer 29 is formed on the second interlayer insulation film 86. The second wiring layer 29 may include at least one of titanium, tungsten, aluminum, copper, an aluminum alloy, a copper alloy, and a conductive polysilicon. The second wiring layer 29 may include at least one of a Cu film (Cu film having purity of 99% or greater), a pure Al film (Al film having purity of 99% or greater), an AlCu alloy film, an AlSi alloy film, and an AlSiCu alloy film.

As described above, the second wiring layer 29 includes the second gate wiring layer 34, the first upper wiring layers 35, the second upper wiring layers 36, and the second base wiring layer 37. The second gate wiring layer 34 is connected by the second gate contact 38, which extends through the second interlayer insulation film 86, to the first gate wiring layer 30 (FIG. 6), and the first upper wiring layers 35 are connected by the first upper contacts 40, which extend through the second interlayer insulation film 86, to the first lower wiring layers 31 (FIG. 6). The second upper wiring layers 36 are connected by the second upper contacts 41, which extend through the second interlayer insulation film 86, to the second lower wiring layers 32 (FIG. 6), and the second base wiring layer 37 is connected by the second base contact 39, which extends through the second interlayer insulation film 86, to the first base wiring layer 33 (FIG. 6).

Referring to FIG. 12, the semiconductor device 1A includes an uppermost insulation film 87 formed on the second interlayer insulation film 86. The uppermost insulation film 87 is not shown in FIGS. 9 to 11. The uppermost insulation film 87 may be part of the insulation layer 9. The uppermost insulation film 87 may be referred to as “the passivation layer.” The uppermost insulation film 87 may have a laminate structure in which an inorganic insulation film (inorganic film) and an organic insulation film (organic film) are laminated in order from the second interlayer insulation film 86. The uppermost insulation film 87 may have a monolayer structure formed by an inorganic insulation film (inorganic film) or an organic insulation film (organic film). Preferably, the inorganic insulation film and the second interlayer insulation film 86 are formed from different insulation materials. The inorganic insulation film may be, for example, a silicon nitride film. The organic insulation film may be formed from a photosensitive resin. The organic insulation film may include at least one of a polyimide film, a polyamide film, and a polybenzoxazole film.

The external terminals 4 to 7 (refer to FIG. 7) are formed on the uppermost insulation film 87. As described above, the external terminals 4 to 7 include the base terminal 4, the gate terminal 5, the first source-drain terminals 6, and the second source-drain terminals 7. The base terminal 4 is connected by the base terminal contact 43, which extends through the uppermost insulation film 87, to the second base wiring layer 37 (FIG. 7), and the gate terminal 5 is connected by the gate terminal contact 42, which extends through the uppermost insulation film 87, to the second gate wiring layer 34 (FIG. 7). The first source-drain terminals 6 are connected by the first terminal contacts 44, which extend through the uppermost insulation film 87, to the first upper wiring layers 35 (FIG. 7), and the second source-drain terminals 7 are connected by the second terminal contacts 45, which extend through the uppermost insulation film 87, to the second upper wiring layers 36 (FIG. 7).

Referring to FIGS. 9 to 12, the semiconductor device 1A includes a second main surface protection film 88 that covers the second main surface 11 of the semiconductor chip 8. In this embodiment, the second main surface protection film 88 entirely covers the second main surface 11 and also covers the first to fourth side surfaces 12A to 12D (FIG. 12). The second main surface protection film 88 may have a monolayer structure formed by an inorganic insulation film (inorganic film) or an organic insulation film (organic film). The inorganic insulation film may be, for example, a silicon nitride film. The organic insulation film may be formed from a photosensitive resin. The organic insulation film may include at least one of a polyimide film, a polyamide film, and a polybenzoxazole film.

Referring to FIGS. 9 to 11, the semiconductor device 1A includes first pn junctions 89 and second pn junctions 90 formed inside the semiconductor chip 8. Each first pn junction 89 is formed in one of the first mesas 53 at the boundary 60A between the first semiconductor region 46A and the second semiconductor region 46B. This forms the first body diode D1 including the second semiconductor region 46B as an anode region and the first semiconductor region 46A as a cathode region in the first mesa 53.

Each second pn junction 90 is formed in one of the second mesas 54 at the boundary 60A between the first semiconductor region 46A and the second semiconductor region 46B. This forms the second body diode D2 including the second semiconductor region 46B as an anode region and the first semiconductor region 46A as a cathode region in the second mesa 54. The anode of the second body diode D2 (second pn junction 90) is electrically connected to the anode of the first body diode D1 (first pn junction 89) by the second semiconductor region 46B.

### Manufacturing Process of Semiconductor Device 1a

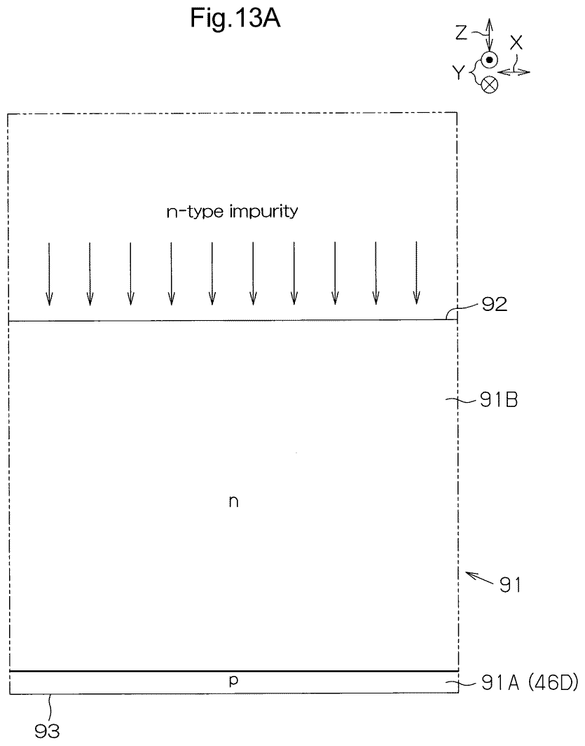

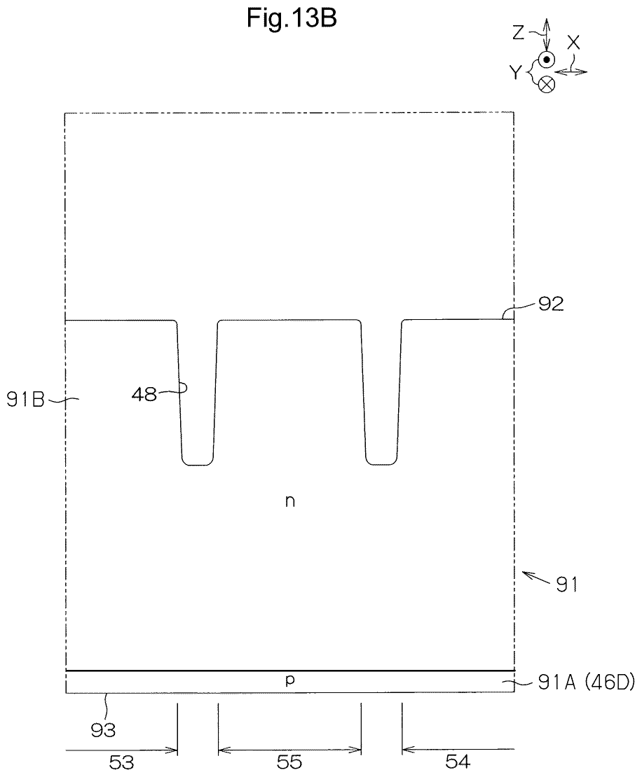

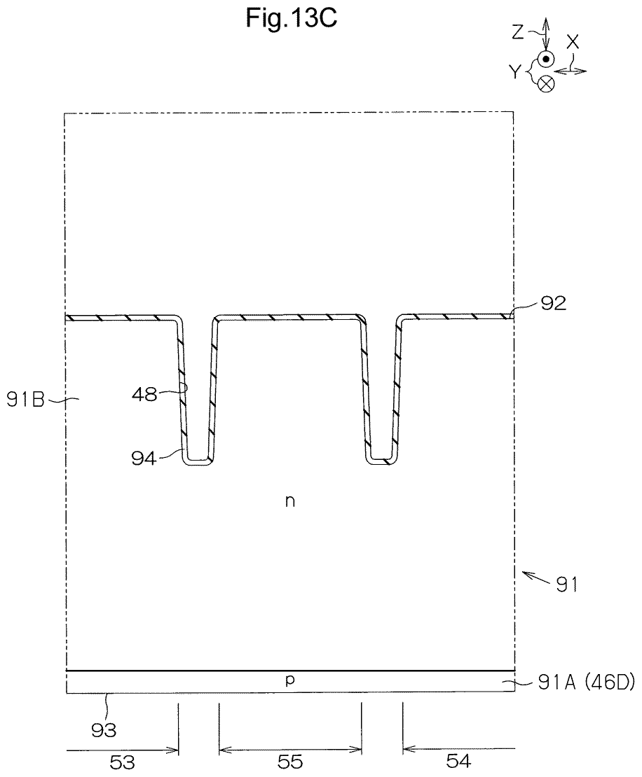

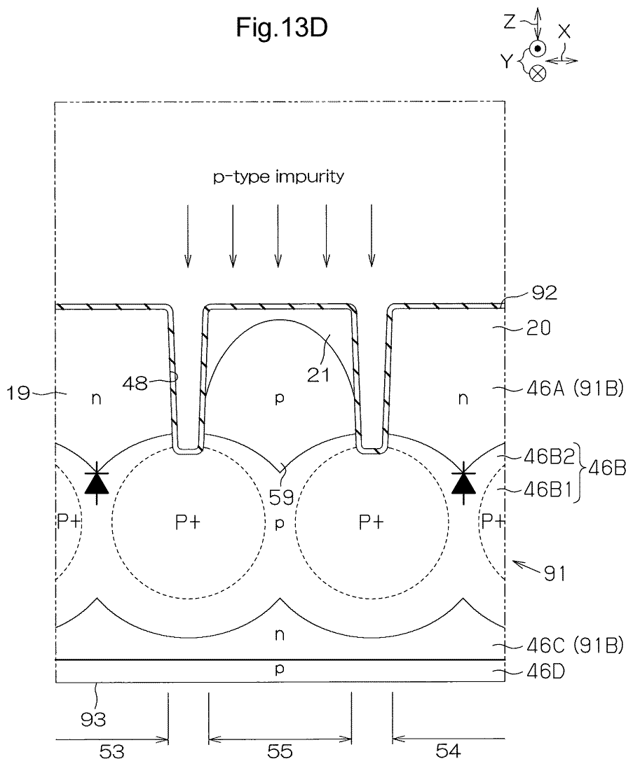

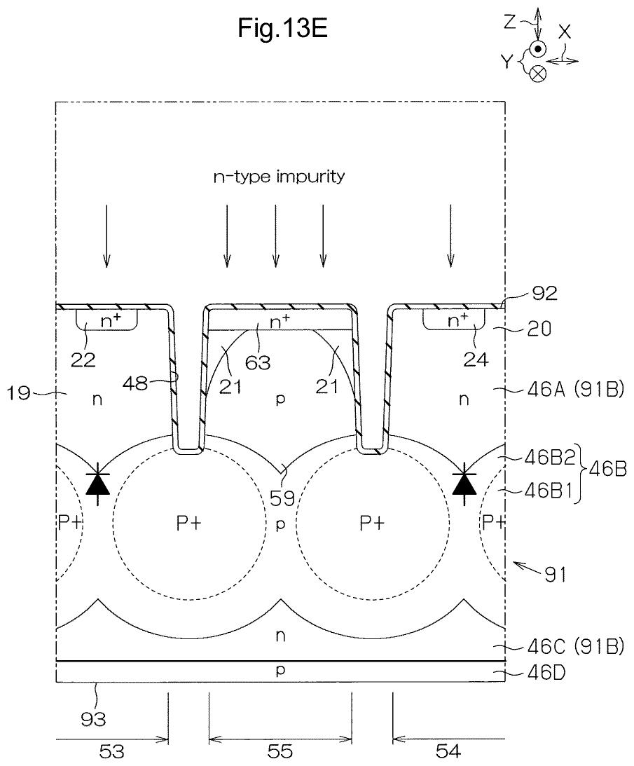

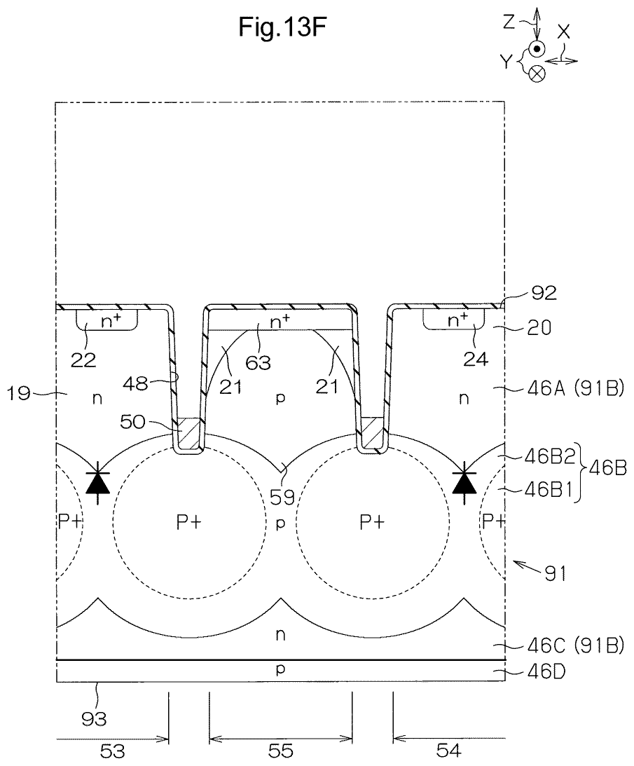

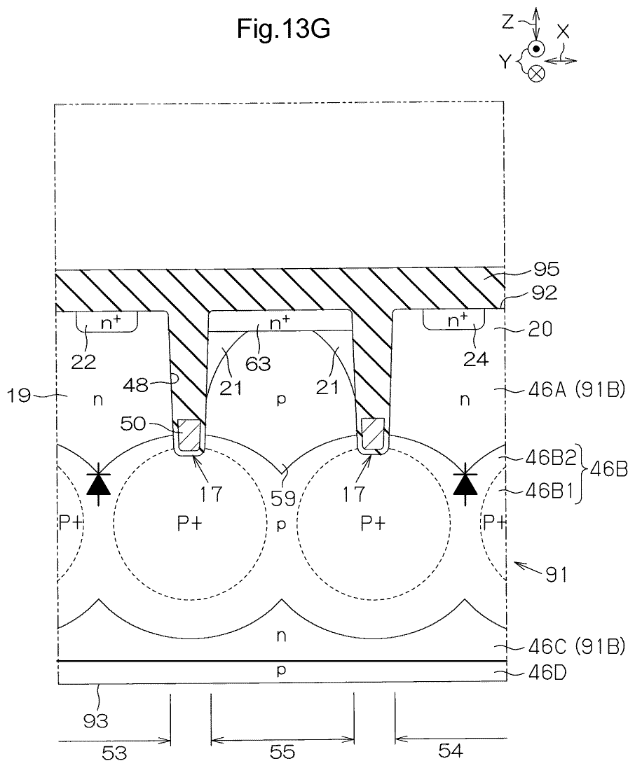

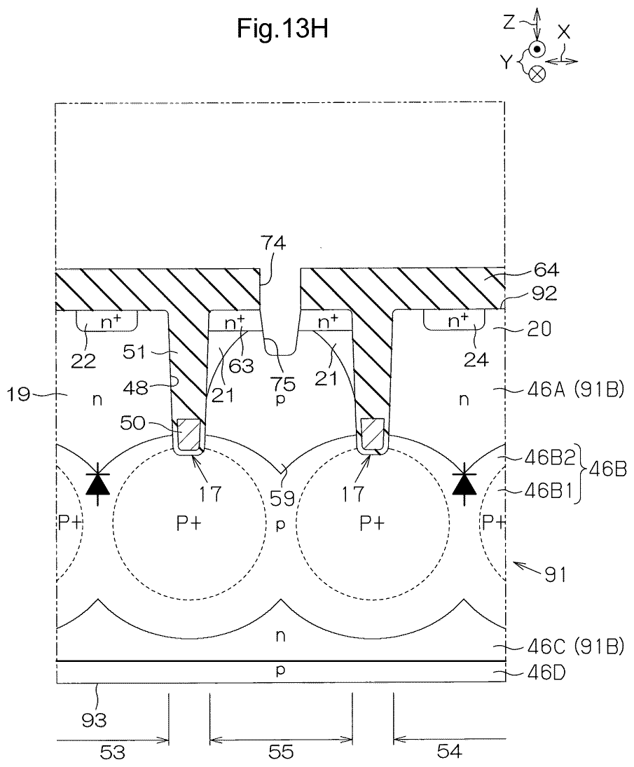

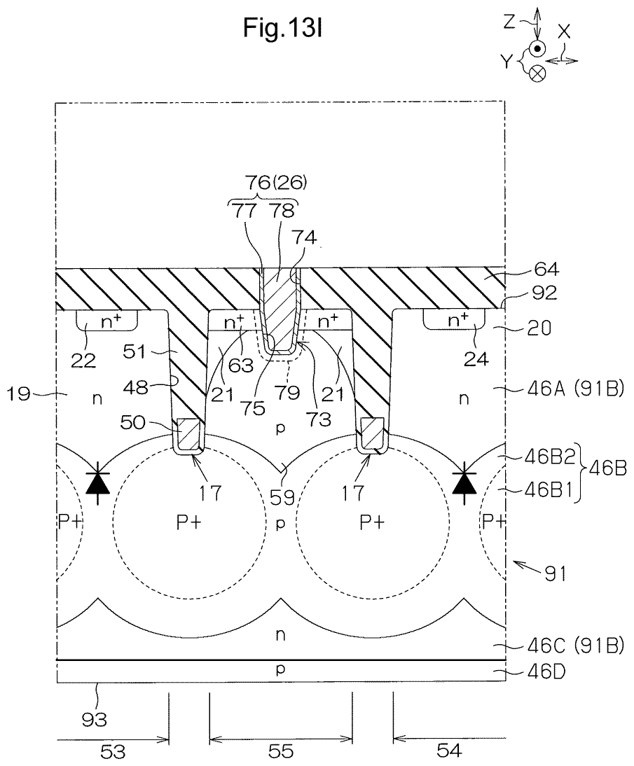

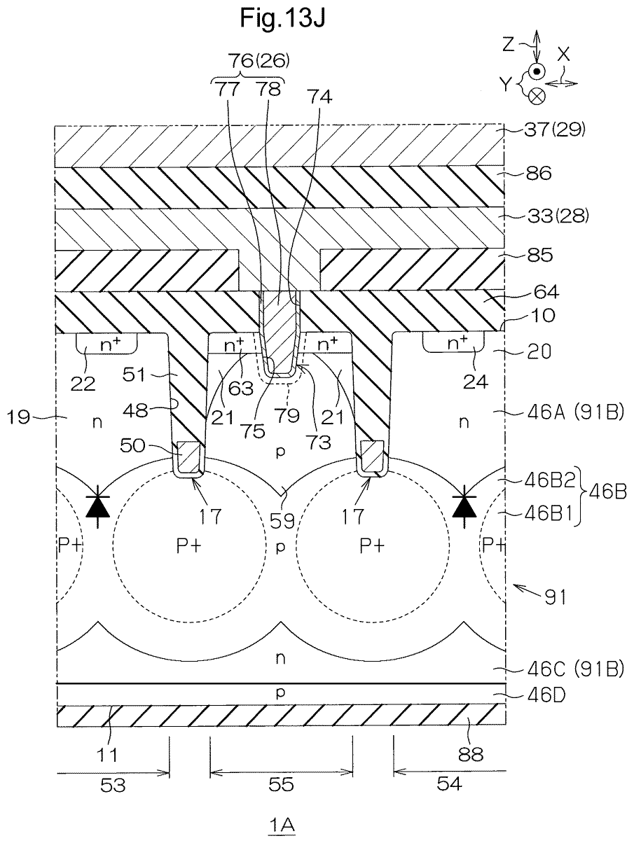

One example of a method for manufacturing the semiconductor device 1A will now be described. FIGS. 13A to 13J are cross-sectional views illustrating one example of a method for manufacturing the semiconductor device 1A of FIG. 1. FIGS. 13A to 13J are cross-sectional views corresponding to the region illustrated in FIG. 11.

Referring to FIG. 13A, a disc-shaped wafer 91 is prepared. The wafer 91 includes a first wafer main surface 92 and an opposite second wafer main surface 93. The wafer 91 is a p-type semiconductor substrate entirely formed by a semiconductor region 91A of the p-type (second conductivity type). Then, a semiconductor region 91B of the n-type is formed in a portion proximate to the first wafer main surface 92. The semiconductor region 91B is formed by performing ion implantation to implant n-type impurities into the portion proximate to the first wafer main surface 92. The n-type impurities may be implanted into the entire portion proximate to the first wafer main surface 92 without using an ion implantation mask. The remaining part of the semiconductor region 91A located near the second wafer main surface 93 where the semiconductor region 91B is not formed becomes the fourth semiconductor region 46D. The implantation of the n-type impurities may be repeated a number of times. This will facilitate the formation of the semiconductor region 91B in which the n-type impurity concentration is relatively high near the first wafer main surface 92 and the n-type impurity concentration is relatively low near the second wafer main surface 93.

The semiconductor region 91B may be formed by performing an epitaxial growth process that grows silicon from the semiconductor region 91A (semiconductor substrate). In this case, the first wafer main surface 92 is formed by the crystal faces (crystal growth faces) of the semiconductor region 91B.

Referring to FIG. 13B, the first trenches 48 and the connection trenches 56 are formed in the first wafer main surface 92. In this step, an etching process is performed using a hard mask (not shown) to selectively remove unnecessary parts from the wafer 91. The etching process may be a wet etching process and/or a dry etching process. Preferably, the etching process is a reactive ion etching (RIE) process, which is one example of a dry etching process. This forms the first trenches 48 and the connection trenches 56. The first trenches 48 (connection trenches 56) partition the mesas 53 to 55 in the first wafer main surface 92. The hard mask is then removed.

Referring to FIG. 13C, a first base insulation film 94, which is a base for the gate insulation films 49 and the connection insulation films 57, is formed on the first wafer main surface 92. The first base insulation film 94 is formed on the first wafer main surface 92 including the walls of the first trenches 48 and the walls of the connection trenches 56. The first base insulation film 94 may be formed through an oxidizing process or a chemical vapor deposition (CVD) process (preferably, thermal oxidizing process).

Referring to FIG. 13D, the second semiconductor region 46B is formed in the semiconductor region 91B. The second semiconductor region 46B divides the semiconductor region 91B into a region extending toward the first wafer main surface 92 from the second semiconductor region 46B and a region extending toward the second wafer main surface 93 from the second semiconductor region 46B. The region extending toward the first wafer main surface 92 from the second semiconductor region 46B defines the first semiconductor region 46A. The region extending toward the second wafer main surface 93 from the second semiconductor region 46B defines the third semiconductor region 46C.

In this step, an ion implantation mask (not shown) having a predetermined pattern is first formed on the first wafer main surface 92. Then, an ion implantation process is performed using the ion implantation mask to selectively inject p-type impurities from the first trenches 48 and the connection trenches 56 into the semiconductor region 91B. This forms the second semiconductor region 46B.

The implantation of the p-type impurities may be repeated a number of times to form the second semiconductor region 46B, which includes the high-concentration regions 46B1 and the low-concentration regions 46B2. When the implantation of the p-type impurities is repeated a number of times, the processing condition may be the same each time the process for implanting the p-type impurities is performed. Alternatively, the processing condition may be changed in every process or in certain processes. The p-type impurities are implanted, for example, twice.

Further, at the same time as when the formation of the second semiconductor region 46B is performed, an ion implantation process is performed using the ion implantation mask to selectively inject p-type impurities from the first wafer main surface 92 to the semiconductor region 91B (first semiconductor region 46A). This forms the projections 59. The hard mask is then removed.

Referring to FIG. 13E, the first contact regions 22, the second contact regions 24, and the first impurity regions 63 are formed. In this step, an ion implantation mask (not shown) having a predetermined pattern is first formed on the first wafer main surface 92. Then, an ion implantation process is performed using the ion implantation mask to selectively inject n-type impurities into the first semiconductor region 46A. This forms the first contact regions 22, the second contact regions 24, and the first impurity regions 63. The hard mask is then removed.

Referring to FIG. 13F, a first base electrode (not shown), which is a base for the gate electrodes 50, the extensions 52, and the connection electrodes 58, is formed on the first wafer main surface 92. The first base electrode is a film that is embedded in the first trenches 48 and the connection trenches 56 and covers the first wafer main surface 92. In this embodiment, the first base electrode includes a conductive polysilicon. The first base electrode may be formed through a CVD process. Then, unnecessary parts are removed from the first base electrode. This forms the gate electrodes 50, the extensions 52, and the connection electrodes 58.

Referring to FIG. 13G, a second base insulation film 95, which is a base for the embedded insulator 51 and the main surface insulation film 64, is formed on the first wafer main surface 92. In this embodiment, the second base insulation film 95 is formed by a silicon oxide film. The second base insulation film 95 may be formed through a CVD process. Preferably, the second base insulation film 95 is formed through a CVD process that is a high-density plasma (HDP)-CVD process.

The second base insulation film 95 is embedded in each recess space defined by the extensions 52 in the first trenches 48 and covers the first wafer main surface 92, the extensions 52, and the connection electrodes 58. This forms the embedded insulators 51, which are located in the first trenches 48, and the main surface insulation film 64, which is located on the first wafer main surface 92.

Referring to FIG. 13H, the first connection openings 66, the second connection openings 70, the third connection openings 81, and the base trenches 75 (base connection openings 74) are formed in the first wafer main surface 92. In this step, a resist mask having a predetermined pattern (not shown) is formed on the main surface insulation film 64. Then, an etching process is performed to remove unnecessary parts from the main surface insulation film 64. The etching process may be a wet etching process and/or a dry etching process (preferably a reactive ion etching (RIE) process). This forms the first connection openings 66, the second connection openings 70, the third connection openings 81, and the base connection openings 74 in the main surface insulation film 64.

Then, an etching process is performed to remove unnecessary parts from the wafer 91 through the resist mask. The etching process may be a wet etching process and/or a dry etching process (preferably an RIE process). Unnecessary parts are removed from the wafer 91 through the first impurity region 63 until the projections 59 become exposed. This forms the base trenches 75 respectively including the base connection openings 74 in the first wafer main surface 92. The resist mask is then removed.

Referring to FIG. 13I, a second base electrode (not shown), which is a base for the first electrodes 65, the second electrodes 69, the base electrodes 76, and the third electrodes 80, is formed on the main surface insulation film 64. In this embodiment, the second base electrode includes a base barrier film and an electrode body film laminated in order from the wafer 91. Then, an etching process is performed to selectively remove unnecessary parts from the second base electrode. The etching process may be a wet etching process and/or a dry etching process (preferably an RIE process). The second base electrode is removed until the main surface insulation film 64 becomes exposed. This forms the first electrodes 65, the second electrodes 69, the base electrodes 76, and the third electrodes 80. After the formation of these electrodes, an annealing process is performed (for example, under a condition in a range from 500° C. to 1100° C., inclusive) to form the silicide layer 79 on the wall of the base trench 75.

Then, referring to FIG. 13J, the first interlayer insulation film 85, the first wiring layer 28, the second interlayer insulation film 86, the second wiring layer 29, the uppermost insulation film 87, the second main surface protection film 88, and the external terminals 4 to 7 are formed, and the wafer 91 is selectively cut in the thickness direction. The semiconductor device 1A is manufactured through the steps described above.

### Operation of Semiconductor Device 1A

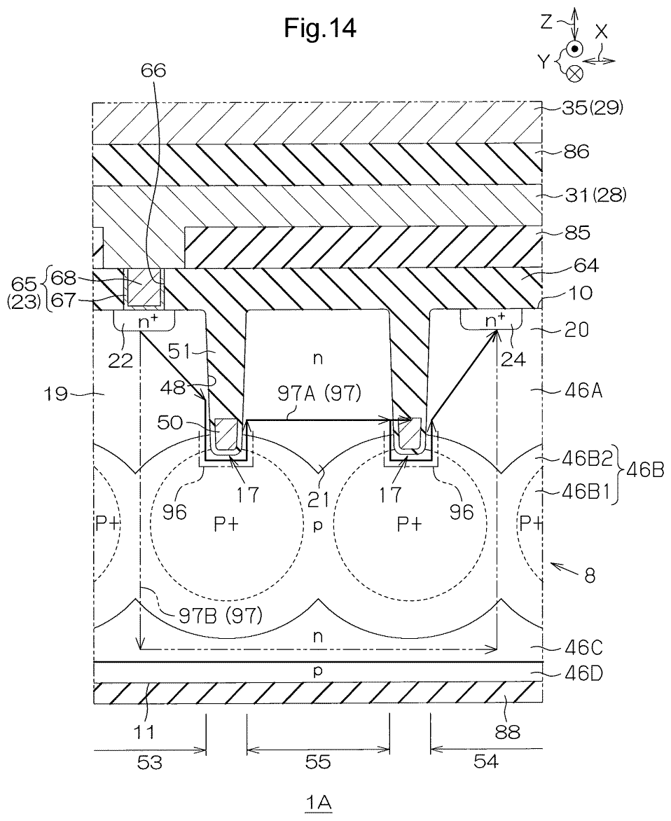

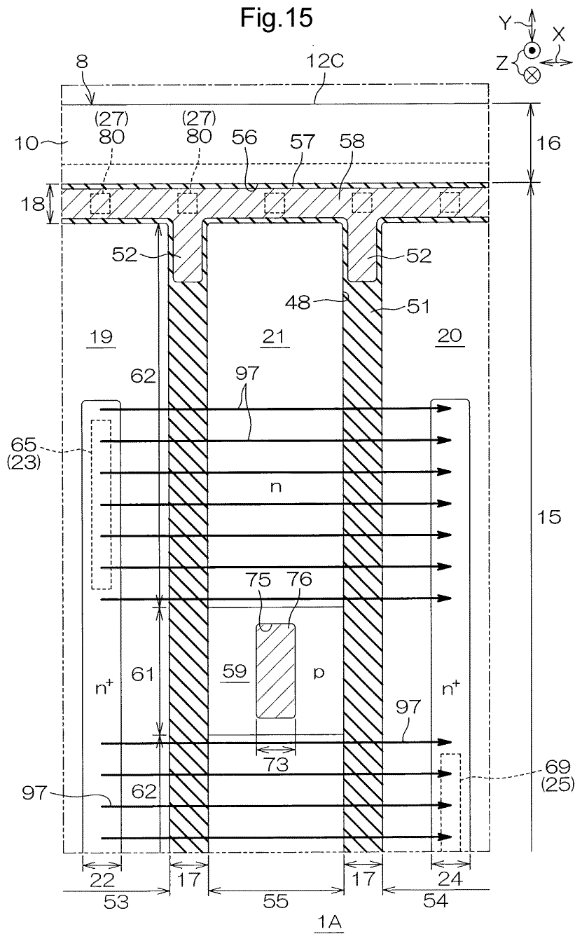

FIG. 14 is a cross-sectional view illustrating current paths 97 of the semiconductor device 1A in accordance with the first embodiment of the present disclosure. FIG. 15 is a plan view illustrating the current paths 97 of the semiconductor device 1A in accordance with the first embodiment of the present disclosure. The current paths 97 include a first current path 97A and a second current path 97B.

The semiconductor device 1A has a MISFET structure of a trench gate-lateral type. In the MISFET structure, gate potential is applied to the first trench structures 17 (gate electrodes 50), drain potential is applied to the first mesas 53, and source potential is applied to the second mesas 54. This forms, in the second semiconductor region 46B, the channel 96 in the region under each first trench structure 17, and the first current path 97A in a lateral direction connecting the first electrodes 65 (first mesas 53) and the second electrodes 69 (second mesas 54).

As shown in FIG. 14, current flows through the first current path 97A in order from the first mesas 53 (first semiconductor region 46A), the second semiconductor region 46B (high-concentration regions 46B1), the drift mesas 55 (first semiconductor region 46A), the second semiconductor region 46B (high-concentration regions 46B1), and the second mesas 54 (first semiconductor region 46A).

When current of a certain amount or greater flows through the first current path 97A, the second current path 97B is additionally formed in the lateral direction connecting the first electrodes 65 (first mesas 53) and the second electrodes 69 (second mesas 54). Current flows through the second current path 97B in the order of the first mesas 53 (first semiconductor region 46A), the second semiconductor region 46B (low-concentration region 46B2), the third semiconductor region 46C, the second semiconductor region 46B (low-concentration region 46B2), and the second mesas 54 (first semiconductor region 46A). The current paths 97 include the second current path 97B in addition to the first current path 97A. This increases the current flowing through the current paths 97. As a result, the on resistance can be decreased.

In the semiconductor device 1A, as shown in FIG. 8, each drift region 21 is divided in the second direction Y into the contact region 61 and the current region 62. The base electrode 76, which fixes the potential (substrate potential) at the second semiconductor region 46B, is selectively formed in the contact region 61 and not formed in the current region 62. This allows the current path 97 connecting the first electrode 65 and the second electrode 69 to be formed over the shortest distance in the current region 62. More specifically, the contact region 61 for fixing the substrate potential is arranged separately from the current region 62 for the current paths 97 so that current flows without bypassing the base electrode 76 thereby decreasing the on resistance.

As shown in FIG. 11, the contact region 61 includes the projection 59 extending toward the first main surface 10. This raises the point where the second trench structure 73 contacts the second semiconductor region 46B toward the first main surface 10 from a boundary 60 of the first semiconductor region 46A and the second semiconductor region 46B. Thus, the second trench structure 73 does not have to extend to the boundary 60, and the substrate potential may be fixed with the relatively shallow second trench structure 73. The shallow base trench 75 ensures contact for the substrate potential with a simple structure.

Referring to FIG. 11, for example, when the second trench structure 73 is deep and further extends toward the second main surface 11 from the boundary 60A, there may be parts where the silicide layer 79 is not formed on the walls of the base trench 75. More specifically, the silicide layer 79 may be locally formed on the bottom wall and the upper end of each side wall of the base trench 75 but the silicide layer 79 may not be formed on other wall parts of the base trench 75. In this respect, in the structure shown in FIG. 11, the base trench 75 is shallow. This allows the silicide layer 79 to be formed entirely on the second trench structure 73. Thus, the base trench 75 has smooth wall surfaces that allow for satisfactory contact between the base electrode body 78 and the base trench 75. This reduces the contact resistance of the base electrode body 78.

The contact regions 61 for fixing the substrate potential are formed in the active region 15. Thus, there is no need for the peripheral region 16 to include a peripheral structure for fixing the substantial potential. This allows the area of the peripheral region 16 to be decreased, and the area of the active region 15 to be increased. As a result, the current characteristics of the semiconductor device 1A can be improved. For example, in the semiconductor device 1A, the occupancy rate of the active region 15 in the first main surface 10 may be in a range of 10% to 99.9%, inclusive.

### Advantages of Semiconductor Device 1A

(1-1) The semiconductor device includes the semiconductor chip 8 including the first main surface 10 and the second main surface 11, the first semiconductor region 46A of the first conductivity type that is formed in the semiconductor chip 8 near the first main surface 10, the second semiconductor region 46B of the second conductivity type that is formed closer to the second main surface 11 than the first semiconductor region 46A is, the trench structures 17 including the trenches 48 extending from the first main surface 10 through the first semiconductor region 46A, and the third semiconductor region 46C of the first conductivity type that is formed closer to the second main surface 11 than the second semiconductor region 46B is. The third semiconductor region 46C and the trench structures 17 sandwich the second semiconductor region 46B.

With this structure, the first current path 97A and the second current path 97B are formed as the current paths 97 extending in the lateral direction and connecting the first electrodes 65 (first mesas 53) and the second electrodes 69 (second mesas 54). This increases the current flowing through the current paths 97 and thereby decreases the on resistance.

(1-2) The thickness of the second semiconductor region 46B immediately below at least one of the first contact region 22 and the second contact region 24 is less than or equal to 10 μm. The thickness is decreased to shorten the distance between the first semiconductor region 46A and the third semiconductor region 46C immediately below the first contact region 22 or immediately below the second contact region 24. Consequently, current that flows through the first current path 97A, which is required to allow current to flow through the second current path 97B, can be decreased. This shortens the time from when current starts to flow through the first current path 97A to when current starts to flow through the second current path 97B. As a result, the effect for reducing the on resistance is improved.

### Modified Examples of the Semiconductor Device 1A

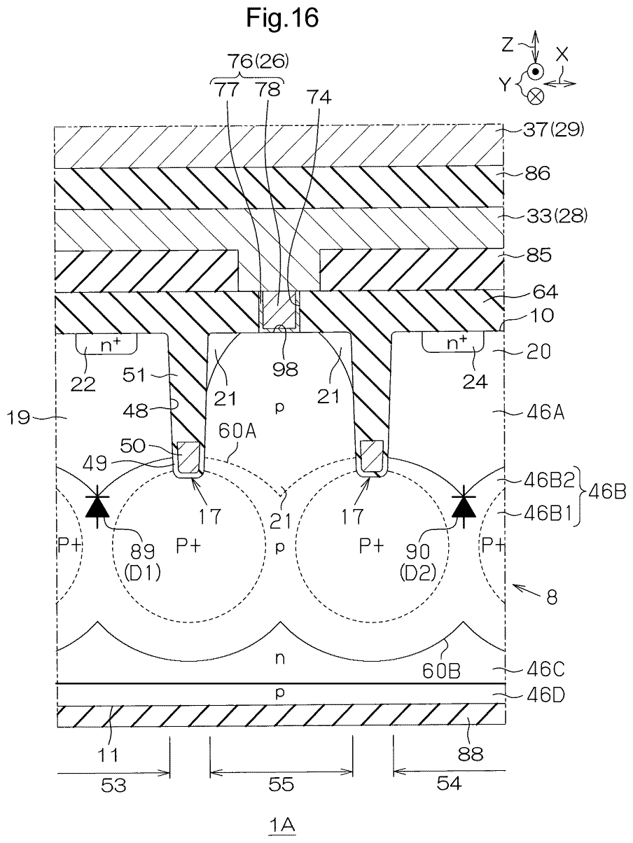

Referring to FIGS. 16 to 18, modified examples of the semiconductor device 1A will now be described.

FIG. 16 is a cross-sectional view illustrating a first modified example of the semiconductor device 1A in accordance with the first embodiment of the present disclosure and corresponding to FIG. 11.

Referring to FIG. 16, the projection 59 may extend from the second semiconductor region 46B through each drift mesa 55 to the first main surface 10. Thus, the projection 59 may include a peak 98 exposed from the first main surface 10 in the contact region 61. In this case, the base electrode 76 does not have to be formed as the second trench structure 73. The base electrode 76 may be embedded in the base connection opening 74 and may have a bottom at the first main surface 10. This connects the base electrode 76 to the projection 59 at the first main surface 10. This structure allows the step of forming the second trench structures 73 to be omitted. Thus, the manufacturing process can be simplified. Further, the material used can be reduced, and the cost of manufacturing can be decreased.

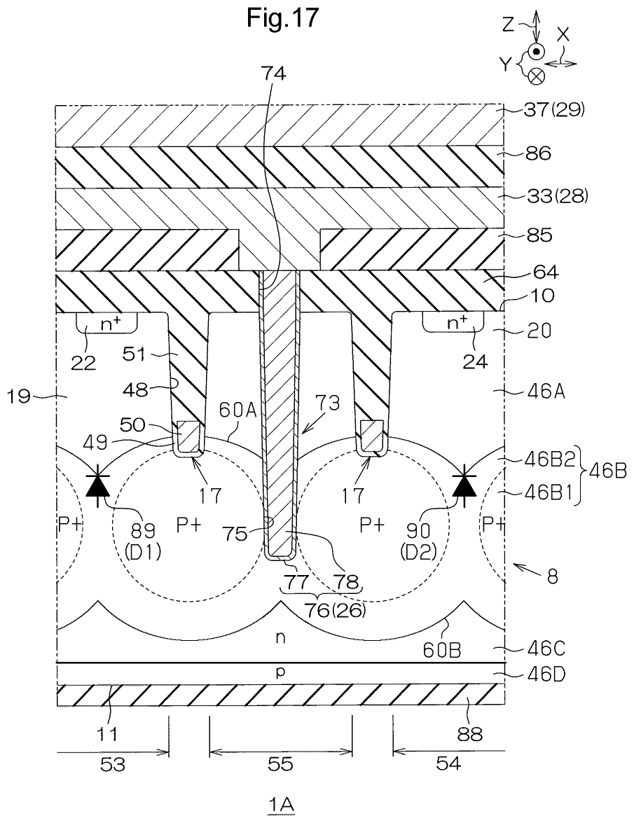

FIG. 17 is a cross-sectional view illustrating a second modified example of the semiconductor device 1A in accordance with the first embodiment of the present disclosure and corresponding to FIG. 11.

Referring to FIG. 17, the second trench structure 73 may be deeper than the first trench structures 17. More specifically, the base trench 75, which is deeper than the first trench 48, may extend across the boundary 60 to the second semiconductor region 46B. This allows the step of forming the projection 59 to be omitted. Thus, the manufacturing process can be simplified. Further, the material used can be reduced, and the cost of manufacturing can be decreased.

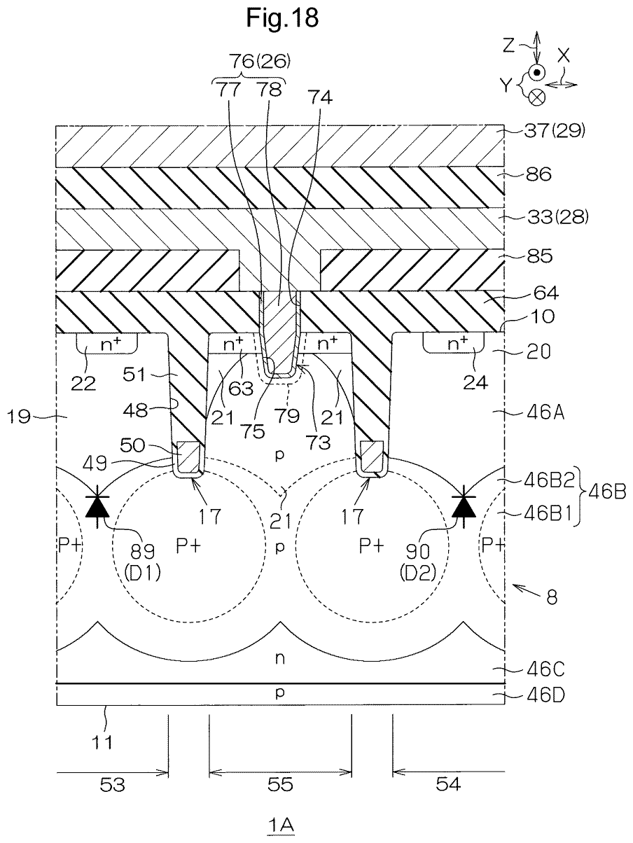

FIG. 18 is a cross-sectional view illustrating a third modified example of the semiconductor device 1A in accordance with the first embodiment of the present disclosure and corresponding to FIG. 11.

Referring to FIG. 18, the second main surface protection film 88 does not have to be formed on the second main surface 11 of the semiconductor chip 8. The second main surface 11 of the semiconductor chip 8 may be an exposed surface. This step allows the step of forming the second main surface protection film 88 to be omitted. Thus, the manufacturing process can be simplified. Further, the material used can be reduced, and the cost of manufacturing can be decreased.

### Second Embodiment

### Structure of Semiconductor Device 1B

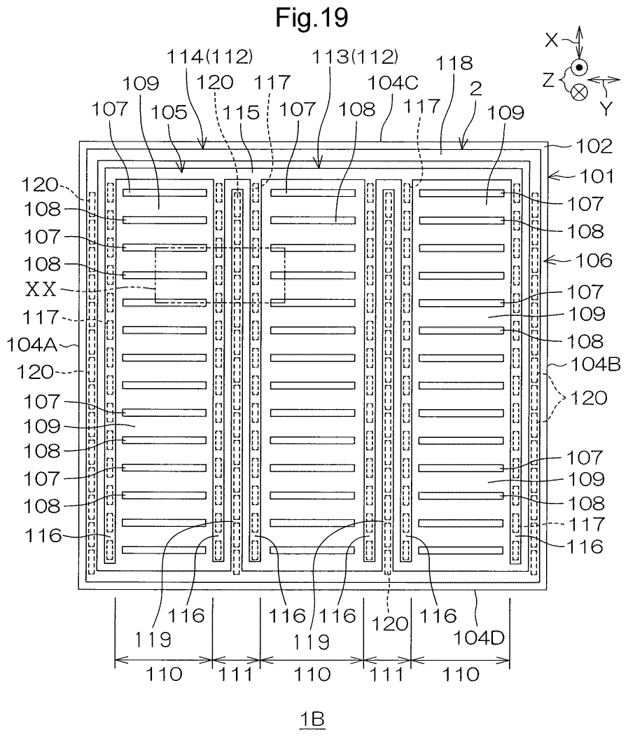

FIG. 19 is a schematic plan view illustrating the internal structure of a semiconductor device 1B in accordance with a second embodiment of the present disclosure. In the second embodiment, the external structure of the semiconductor device 1B such as the arrangement of the external terminals 4 to 7 shown in FIGS. 2 and 3 will not be described, and the internal structure of the semiconductor device 1B will be described.

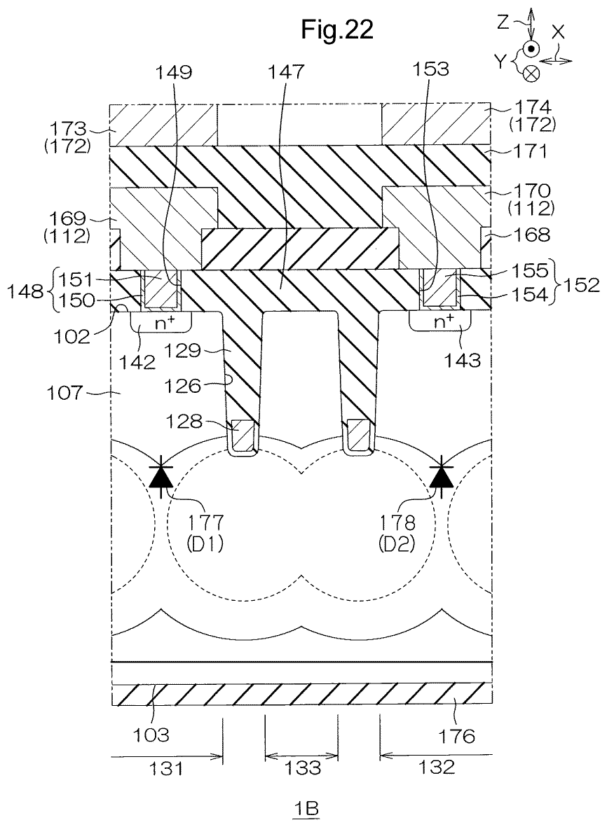

The semiconductor device 1B includes a semiconductor chip 101. The semiconductor chip 101 has the form of a rectangular parallelepiped. The semiconductor chip 101 includes a first main surface 102, an opposite second main surface 103 (refer to drawings from FIG. 22), and side surfaces 104A, 104B, 104C, and 104D connecting the first main surface 102 and the second main surface 103. The side surfaces 104A to 104D are, specifically, the first side surface 104A, the second side surface 104B, the third side surface 104C, and the fourth side surface 104D.

The first main surface 102 of the semiconductor chip 101 includes an active region 105 and a peripheral region 106 surrounding the active region 105.

The peripheral region 106 may have a closed shape and extend along the side surfaces 104A to 104D of the semiconductor chip 101. The peripheral region 106 may be a region having a closed shape and extending a few nanometers inward from the side surfaces 104A to 104D of the semiconductor chip 101. The active region 105 may be a central region of the semiconductor chip 101 surrounded by the peripheral region 106. The active region 105 is, for example, a region occupying most of the element structure of the MISFET 2.

The element structure of the MISFET 2 is formed in the active region 105. In this embodiment, the element structure is a metal insulator semiconductor field effect transistor (MISFET) of a trench gate-lateral type.

The MISFET 2 includes first source-drain regions 107, second source-drain regions 108, and draft regions 109 as the element structure formed in the active region 105.

In this embodiment, the first source-drain regions 107 and the second source-drain regions 108 are alternately arranged at intervals in the first direction X. Each first source-drain region 107 and the adjacent second source-drain region 108 sandwich one of the draft regions 109. Thus, the first source-drain region 107 and the second source-drain region 108 are located at opposite sides of the draft region 109. Sets of the first source-drain region 107, the draft region 109, the second source-drain region 108, and the draft regions 109 in order from the upper side as viewed in FIG. 19 are arranged repetitively in the first direction X.

The first main surface 102 includes sections in which the first source-drain region 107, the second source-drain region 108, and the draft region 109 are arranged repetitively. Each section defines a cell region 110. A wiring region 111 extending in the first direction X is defined between adjacent cell regions 110. In this embodiment, two wiring regions 111, which extend in the first direction X, divide the first main surface 102 into three parts. The cell regions 110 are the regions sandwiched between two wiring regions 111 and the regions formed at the outer side of each wiring regions 111 in the second direction Y. Thus, multiple (three in FIG. 19) cell regions 110 are arranged at intervals in the second direction Y. Each wiring region 111 extends in the first direction X between adjacent cell regions 110 and across the vicinity of each end of the first source-drain regions 107 and the second source-drain regions 108.

Each cell region 110 includes strips of the first source-drain regions 107 and the second source-drain regions 108 extending in the second direction Y. The first source-drain regions 107, the second source-drain regions 108, and the draft regions 109 are arranged in a regular manner so that the same region type are aligned in the second direction Y.

From the upper side as viewed In FIG. 19, rows of the first source-drain regions 107 aligned in the second direction Y are alternately arranged with rows of the second source-drain regions 108 aligned in the second direction Y. Between each row of the first source-drain regions 107 and the adjacent row of the second source-drain regions 108, a row of the draft regions 109 is aligned in the second direction Y. Thus, the first source-drain regions 107, the second source-drain regions 108, and the draft regions 109 are arranged so that the same type of regions are aligned in the second direction Y. In other words, in FIG. 19, the strips of the first source-drain regions 107, the second source-drain regions 108, and the draft regions 109 extending in the second direction Y are separated into multiple parts by the wiring regions 111. In this case, each part may include a single first source-drain region 107, a single second source-drain region 108, and a single draft region 109.

Multiple wiring layers are formed on the first main surface 102 of the semiconductor chip 101, and the external terminals described above are connected to the uppermost wiring layer. The wiring layers form a multi-layer wiring structure. FIG. 19 shows only a first wiring layer 112.

The first wiring layer 112 may be referred to as “the first metal.” The first wiring layer 112 includes a first gate wiring layer 113 and a first base wiring layer 114. The first wiring layer 112 includes further layers, which will be described later. The first gate wiring layer 113 is physically independent from the first base wiring layer 114.

The first gate wiring layer 113 includes a gate peripheral portion 115 extending along the peripheral region 106, and gate branching portions 116 extending from the gate peripheral portion 115 toward the inner side of the semiconductor chip 101 along the edges of the wiring regions 111 and the edges of the semiconductor chip 101. The gate peripheral portion 115 extends straight along the third side surface 104C, that is, at one side of the cell regions 110 in the first direction X. The gate branching portions 116 that extend from the longitudinally intermediate part of the gate peripheral portion 115 are arranged in pairs extending straight along the wiring regions 111. The pairs of the gate branching portions 116 are parallel to one another. The other gate branching portions 116 extend straight from the two ends of the gate peripheral portion 115 on the peripheral region 106.

The first gate wiring layer 113 is connected to first gate contacts 117. In this embodiment, the first gate contacts 117 are covered by the gate branching portions 116. In each gate branching portion 116, the first gate contacts 117 are arranged at intervals in the first direction X.

The first base wiring layer 114 includes a base peripheral portion 118 extending along the peripheral region 106, and base branching portions 119 extending from the base peripheral portion 118 toward the inner side of the semiconductor chip 101 on the wiring region 111. The base peripheral portion 118 has the form of a closed loop and collectively surrounds the cell regions 110 and the first gate wiring layer 113. In this embodiment, the base peripheral portion 118 has the form of a square loop in plan view. The base branching portions 119 each extend straight from a longitudinally intermediate part of the base peripheral portion 118 along the wiring regions 111. In this embodiment, each base branching portion 119 is arranged between and sandwiched by the two gate branching portions 116 in the corresponding wiring region 111.

The first base wiring layer 114 is connected to first base contacts 120. In this embodiment, the first base contacts 120 are covered by the base branching portions 119. In each base branching portion 119, the first base contacts 120 are arranged at intervals in the first direction X.

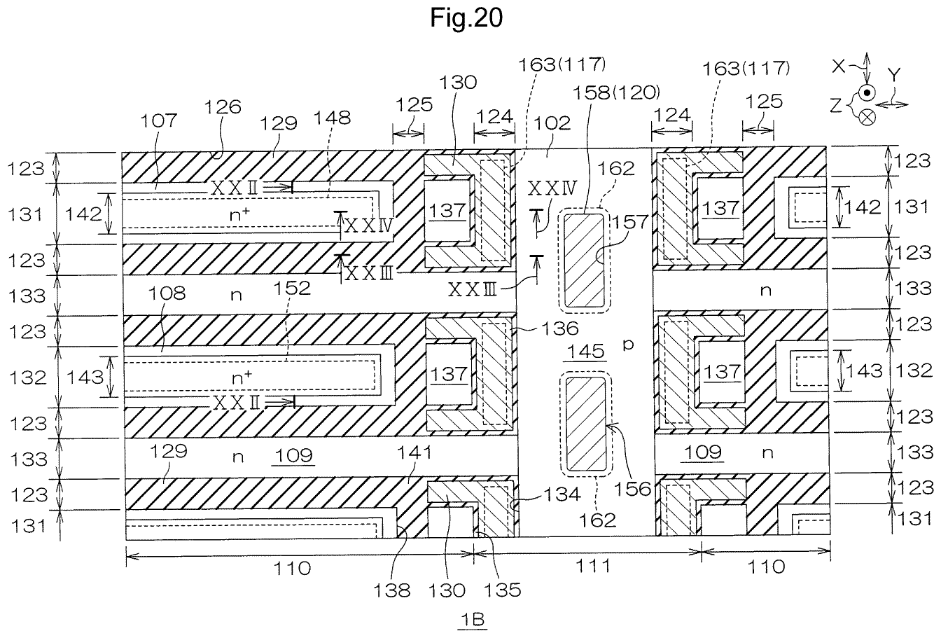

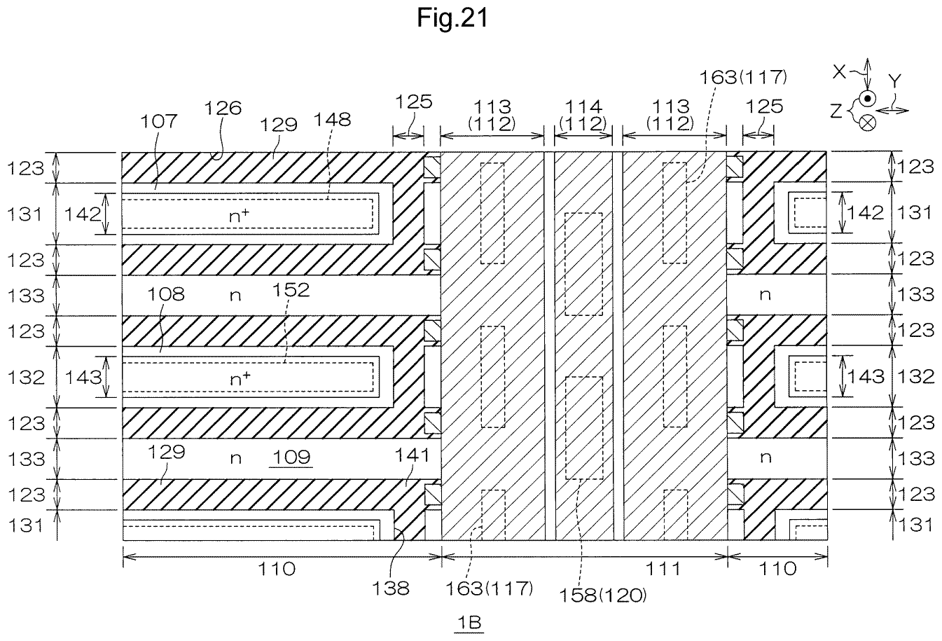

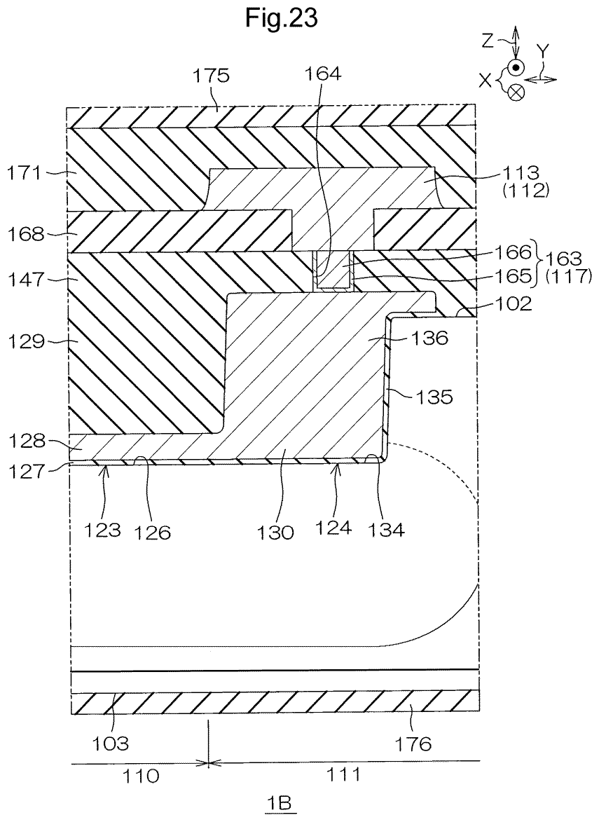

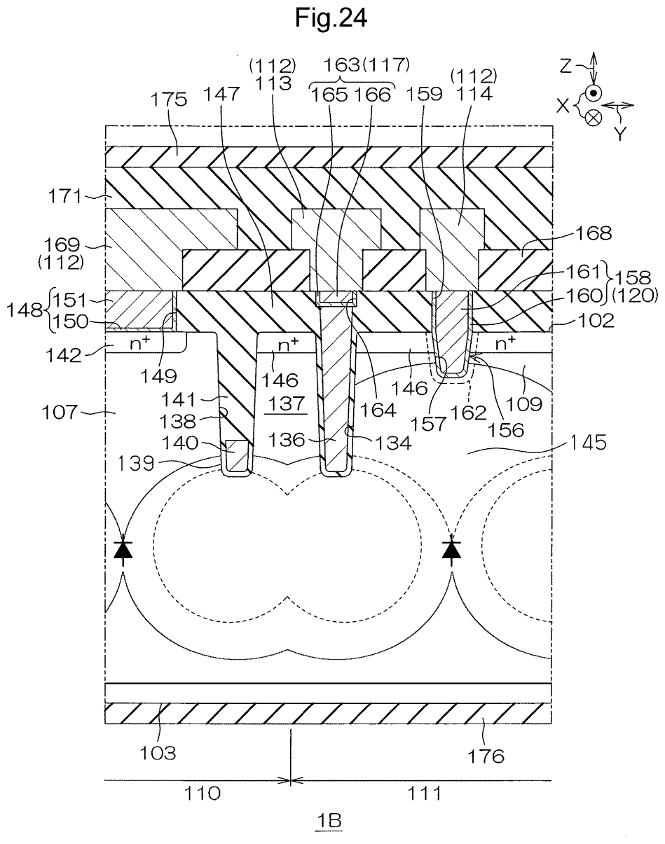

FIG. 20 is an enlarged view showing the part surrounded by double-dashed line XX in FIG. 19. FIG. 21 is an enlarged view showing the part surrounded by double-dashed line XX in FIG. 19. FIG. 22 is a cross-sectional view taken along line XXII-XXII in FIG. 20. FIG. 23 is a cross-sectional view taken along line XXIII-XXIII in FIG. 20. FIG. 24 is a cross-sectional view taken along line XXIV-XXIV in FIG. 20.

Referring to FIGS. 20 to 24, the semiconductor device 1B includes the semiconductor chip 101. The semiconductor chip 101 is, for example, a monolayer semiconductor chip. The monolayer semiconductor chip 101 is a single-structure semiconductor substrate that does not have an epitaxial layer. In this embodiment, the semiconductor chip 101 does not have an epitaxial layer and includes silicon (Si) monocrystals or wide bandgap semiconductor monocrystals. A wideband semiconductor has a wider bandgap than a Si bandgap. The semiconductor chip 101 may be a Si chip or a silicon carbide (SiC) chip.

The semiconductor device 1B includes a first semiconductor region 121A of the n-type (first conductivity type) formed in the semiconductor chip 101 at a region near the first main surface 102. The first semiconductor region 121A is referred to as “the drift layer.” The first semiconductor region 121A is formed in the semiconductor chip 101 spaced apart from the second main surface 103 and located near the first main surface 102. The first semiconductor region 121A, which has the form of a layer, is located proximate to the first main surface 102 and extends along the first main surface 102 entirely exposed from the first main surface 102 and partially exposed from the first to fourth side surfaces 104A to 104D.

The first semiconductor region 121A may be separated from the first to fourth side surfaces 104A to 104D and formed inward from the first main surface 102. The structure of the first semiconductor region 121A is similar to the structure of the first semiconductor region 46A in the semiconductor device 1A described above.

The semiconductor device 1B includes a second semiconductor region 121B of the p-type (second conductivity type) formed in the semiconductor chip 101 closer to the second main surface 103 than the first semiconductor region 121A. The structure of the second semiconductor region 121B is similar to the structure of the second semiconductor region 46B in the semiconductor device 1A described above.

The semiconductor device 1B includes a third semiconductor region 121C of the n-type (first conductivity type) that is formed in the semiconductor chip 101 closer to the second main surface 103 than the second semiconductor region 121B is. The structure of the third semiconductor region 121C is similar to the structure of the third semiconductor region 46C in the semiconductor device 1A described above.

The semiconductor device 1B includes a fourth semiconductor region 121D of the p-type (second conductivity type) that is formed in the semiconductor chip 101 closer to the second main surface 103 than the third semiconductor region 121C is. The fourth semiconductor region 121D may be referred to as “the base layer.” The structure of the fourth semiconductor region 121D is similar to the structure of the fourth semiconductor region 46D in the semiconductor device 1A described above.

The MISFET 2 includes trench structures formed in the first main surface 102, namely, first trench structures 123, trench connecting structures 124, and trench breakdown voltage structures 125.

The first trench structures 123 may each be referred to as “the trench gate structure.” The first trench structures 123 are arranged at intervals in the first direction X and have the form of strips extending in the second direction Y. The first trench structures 123 are arranged in a striped pattern extending in the second direction Y in plan view. In the second direction Y, each first trench structure 123 includes a first end at one side and a second end at the other side.

The first trench structures 123 extend through the first semiconductor region 121A to the second semiconductor region 121B. In this embodiment, each first trench structure 123 includes a bottom wall located in the second semiconductor region 121B. The first trench structures 123 are each configured to control the reversion and non-reversion of a channel (described later as channel 184) in the second semiconductor region 121B.

The first trench structures 123 may be arranged at an interval (pitch) in a range from 0.03 μm to 10 μm, inclusive (preferably, in a range from 0.1 μm to 0.3 μm, inclusive). Preferably, the first trench structures 123 are arranged at equal intervals in the first direction X. The first trench structures 123 may each have a width in the first direction X in a range from 0.01 μm to 10 μm, inclusive (preferably, in a range from 0.1 μm to 0.5 μm, inclusive). The first trench structures 123 may each have a depth in a range from 0.2 μm to 30 μm, inclusive (preferably, in a range from 0.5 μm to 10 μm, inclusive).

The internal structure of one of the first trench structures 123 will now be described. The first trench structure 123 includes a first trench 126, a gate insulation film 127 (control insulation film), a gate electrode 128 (control electrode), and an embedded insulator 129.

The first trench 126 may be referred to as “the gate trench.” The first trench 126 is formed in the first main surface 102 and defined by the wall surfaces (side walls and bottom wall) of the first trench structure 123. The first semiconductor region 121A and the second semiconductor region 121B are exposed from the wall surfaces of the first trench 126.

The first trench 126 may be tapered so that its width narrows from the first main surface 102 toward the bottom side in a cross-sectional view. The first trench 126 may extend at a right angle from the first main surface 102. The first trench 126 may have curved bottom corners. The bottom wall of the first trench 126 may be entirely curved toward the second main surface 103.

The gate insulation film 127 covers the side walls and bottom wall of the first trench 126. In this embodiment, the gate insulation film 127 covers the side walls and bottom wall of the first trench 126 and defines a recess space near the bottom wall of the first trench 126. The gate insulation film 127 may have a thickness in a range from 5 nm to 1000 nm, inclusive, in a direction normal to the wall surface of the first trench 126. The gate insulation film 127 may be at least one of a silicon oxide film, a silicon nitride film, an aluminum oxide film, a zirconium oxide film, a hafnium oxide film, and a tantalum oxide film. Preferably, the gate insulation film 127 is formed by a silicon oxide film. In particular, the gate insulation film 127 is preferably formed by an oxide (thermally oxidized film) of the semiconductor chip 101.

The gate electrode 128 is embedded in the first trench 126 with the gate insulation film 127 interposed. More specifically, the gate electrode 128, which is embedded in the recess space defined by the gate insulation film 127 near the bottom wall of the first trench 126, opposes the second semiconductor region 121B with the gate insulation film 127 interposed. The gate electrode 128 extends across a boundary 144A of the first semiconductor region 121A and the second semiconductor region 121B in a depth direction of the first trench 126.

The gate electrode 128 includes extensions 130 extending from the bottom side toward the open side of the first trench 126. There may be any number of extensions 130. In this embodiment, there are two extensions 130 spaced part in the second direction Y. In this embodiment, the two extensions 130 are respectively formed at the two ends of the first trench 126. The extensions 130 each extend in the second direction Y in plan view.

An open side recess is defined between each extension 130 and the wall surface of the corresponding first trench 126 at the open side of the first trench 126. The open side recess has the form of a slit extending in the second direction Y. The extension 130 may extend upward from the first main surface 102. The extension 130 may extend out of the first trench 126 over the first main surface 102 with part of the gate insulation film 127 interposed. The extensions 130 may be located closer to the bottom of the first trench 126 than to the first main surface 102.

The gate electrode 128 may include at least one of a metal conductor and a non-metal conductor. The gate electrode 128 may include at least one of tungsten, aluminum, copper, an aluminum alloy, a copper alloy, and a conductive polysilicon. Preferably, the gate electrode 128 includes a non-metal conductor (conductive polysilicon). The conductive polysilicon may be a p-type polysilicon or an n-type polysilicon. Preferably, the conductive polysilicon is an n-type polysilicon.

The embedded insulator 129 is embedded in the first trench 126 at the open side of the first trench 126 and covers the gate electrode 128. More specifically, the embedded insulator 129 is embedded in the open side recess defined by the gate electrode 128. The embedded insulator 129 corresponds to a field insulator that reduces the electric field at the first trench 126. The area of the embedded insulator 129 facing the first semiconductor region 121A is greater than the area of the gate electrode 128 facing the second semiconductor region 121A.

The embedded insulator 129 has a greater thickness than the gate electrode 128 in the depth direction of the first trench 126. The embedded insulator 129 may be at least one of a silicon oxide film, a silicon nitride film, an aluminum oxide film, a zirconium oxide film, a hafnium oxide film, and a tantalum oxide film. Preferably, the embedded insulator 129 is formed by a silicon oxide film. Preferably, the embedded insulator 129 is formed from the same material as the gate insulation film 127. In this case, preferably, the embedded insulator 129 is formed by an insulative vapor deposition film and has a density that differs from that of the gate insulation film 127.

The semiconductor device 1B includes mesas 131 to 133 defined by the first trench structures 123 in the first main surface 102 (first semiconductor region 121A). The mesas 131 to 133 are strips, each extending in the second direction Y between two adjacent ones of the first trench structures 123. The mesas 131 to 133 include the first mesas 131, the second mesas 132, and the drift mesas 133.

Each first mesa 131 is distanced in the first direction X from the adjacent second mesa 132 with a drift mesa 133 interposed. The first mesas 131 are formed in the first source-drain regions 107 and may each be referred to as “the first source-drain mesa.” The second mesas 132 are formed in the second source-drain regions 108 and may each be referred to as “the second source-drain mesa.” The drift mesas 133 form the drift regions 109.

The trench connection structures 124 are connected to the first trench structures 123. The trench connecting structures 124 include trench connecting structures 124 connected to first ends of the first trench structures 123 and trench connecting structures 124 connected to second ends of the first trench structures 123.

In this embodiment, the trench connecting structures 124 connect the ends of two adjacent first trench structures 123 in the first direction X. More specifically, the first ends of two adjacent first trench structure 123 are connected by a trench connecting structure 124, and the second ends of the two adjacent first trench structure 123 are connected by another trench connecting structure 124. This forms regions in the first main surface 10 that are surrounded and closed by two first trench structures 123 and two trench connection structures 124.

Two first trench structures 123 and two trench connecting structures 124 define a first source-drain region 107 or a second source-drain region 108. More specifically, the semiconductor device 1B includes, in the first main surface 102, the first source-drain regions 107 and the second source-drain regions 108, each of which are separated and independent from one another and surrounded by a trench structure that is rectangular in plan view and formed by two first trench structures 123 and two trench connecting structures 124.

The first trench structures 124 extend through the first semiconductor region 121A to the second semiconductor region 121B. The trench connecting structures 124 define the first trench structures 123 and the mesas 131 to 133 (first mesas 131, second mesas 132, and the drift mesas 133).

The trench connection structures 124 may each have a width in the second direction Y in a range from 0.01 μm to 10 μm, inclusive (preferably, in range from 0.1 μm to 2 μm, inclusive). The width of each trench connection structure 124 may be substantially equal to that of each first trench structure 123. The trench connection structure 124 may each have a depth in a range from 0.2 μm to 30 μm, inclusive (preferably, in a range from 0.5 μm to 10 μm, inclusive). The depth of each trench connection structure 124 may be substantially equal to that of each first trench structure 123.

Each trench connecting structure 124 includes a connection trench 134, a connection insulation film 135, and a connection electrode 136. The connection trench 134, formed in the first main surface 102, is connected to the first trenches 126 and defined by the wall surfaces (side walls and bottom wall) of the trench connection structure 124. The wall surfaces (side walls and bottom wall) of each trench connection structure 124 is continuously integrated with the wall surfaces (side wall and bottom wall) of the corresponding first trenches 126. The first semiconductor region 121A and the second semiconductor region 121B are exposed from the wall surfaces of the connection trench 134.

The connection trench 134 may be tapered so that its width narrows from the first main surface 102 toward the bottom side in a cross-sectional view. The connection trench 134 may extend at a right angle from the first main surface 102. The connection trench 134 may have curved bottom corners. The bottom wall of the connection trench 134 may be entirely curved toward the second main surface 103.

The connection insulation film 135 covers the side walls and the bottom wall of the connection trench 134. In this embodiment, the connection insulation film 135 covers the side walls and the bottom wall at the open side and the bottom side of the connection trench 134 and defines a recess space in the connection trench 134. The connection insulation film 135 is continuously integrated with the gate insulation films 127 of the connected first trenches 126.

The connection insulation film 135 may have a thickness in a range from 5 nm to 1000 nm, inclusive. Preferably, the connection insulation film 135 has substantially the same thickness as the gate insulation film 127. The connection insulation film 135 may be at least one of a silicon oxide film, a silicon nitride film, an aluminum oxide film, a zirconium oxide film, a hafnium oxide film, and a tantalum oxide film. Preferably, the connection insulation film 135 is formed from the same material as the gate insulation layer.

The connection electrode 136, which is embedded in the connection trench 134 with the connection insulation film 135 interposed, opposes the first semiconductor region 121A and the second semiconductor region 121B. The connection electrode 136 is continuous with the gate electrodes 128 in the first trenches 126. More specifically, the connection electrode 136 is continuous with the extensions 130. This fixes the connection electrode 136 at the same potential as the gate electrodes 128.

The portions of the connection electrode 136 that are continuous with the extensions 130 may be elements of the connection electrode 136 or elements of the gate electrodes 128. The connection electrode 136 has an upper end that is closer to the first main surface 102 than the upper ends of the gate electrodes 128 are. The connection electrode 136 may project upward from the first main surface 102. The connection electrode 136 may extend out of the connection trench 134 over the first main surface 102 with part of the connection insulation film 135 interposed. The connection electrode 136 may be located closer to the bottom of the connection trench 134 than to the first main surface 102.

The connection electrode 136 may include at least one of a metal conductor and a non-metal conductor. The connection electrode 136 may include at least one of tungsten, aluminum, copper, an aluminum alloy, a copper alloy, and a conductive polysilicon. Preferably, the connection electrode 136 is formed from the same material as the gate electrode 128.

Referring to FIG. 20, each trench breakdown voltage structure 125 extends between two first trench structures 123 in the first direction X. More specifically, each trench breakdown voltage structure 125 extends from one first trench structure 123 to the other first trench structure 123 across the corresponding first source-drain region 107 or the corresponding second source-drain region 108 and separates the end part of the first source-drain region 107 or the second source-drain region 108 from the remaining part.

This forms a separating region 137 that separates part of the corresponding first source-drain region 107 or the corresponding second source-drain region 108 from the remaining part between the trench connecting structure 124 and the trench breakdown voltage structure 125. The separating region 137 is surrounded by two first trench structures 123, the trench connecting structure 124 and the trench breakdown voltage structure 125. The formation of the separating region 137 results in the corresponding first source-drain region 107 or the corresponding second source-drain region 108 being separated by the separating region 137 in the second direction Y from the trench connecting structure 124.

The trench breakdown voltage structure 125 covers the end part of the corresponding first source-drain region 107 or the corresponding second source-drain region 108 at a portion separated from the trench connecting structure 124 in the second direction Y.

The trench breakdown voltage structures 125 extend through the first semiconductor region 121A to the second semiconductor region 121B. In this embodiment, each trench breakdown voltage structure 125 includes a bottom wall located in the second semiconductor region 121B.

The trench breakdown voltage structures 125 may each have a width in the second direction Y in a range from 0.01 μm to 10 μm, inclusive (preferably, in range from 0.1 μm to 2 μm, inclusive). The width of each trench breakdown voltage structure 125 may be substantially equal to that of each first trench structure 123. The trench breakdown voltage structure 125 may each have a depth in a range from 0.2 μm to 30 μm, inclusive (preferably, in a range from 0.5 μm to 10 μm, inclusive). The depth of each trench breakdown voltage structure 125 may be substantially equal to that of each first trench structure 123.

Each trench breakdown voltage structure 125 includes a breakdown voltage trench 138, a breakdown voltage film 139, a breakdown voltage electrode 140, and a breakdown voltage insulator 141.

The breakdown voltage trench 138 is formed in the first main surface 102 and defined by the wall surfaces (side walls and bottom wall) of the trench breakdown voltage structure 125. The wall surfaces (side walls and bottom wall) of the trench breakdown voltage structure 125 are continuously integrated with the wall surfaces (side walls and bottom wall) of the corresponding first trenches 126. The first semiconductor region 121A and the second semiconductor region 121B are exposed from the wall surfaces of the breakdown voltage trench 138.

The breakdown voltage trench 138 may be tapered so that its width narrows from the first main surface 102 toward the bottom side in a cross-sectional view. The breakdown voltage trench 138 may extend at a right angle from the first main surface 102. The breakdown voltage trench 138 may have curved bottom corners. The bottom wall of the breakdown voltage trench 138 may be entirely curved toward the second main surface 103.

The breakdown voltage film 139 covers the side walls and the bottom wall of the breakdown voltage trench 138. In this embodiment, the breakdown voltage film 139 covers the side walls and the bottom wall of the breakdown voltage trench 138 and defines a recess space near the bottom wall of the breakdown voltage trench 138. The breakdown voltage film 139 is continuously integrated with the gate insulation film 127. The breakdown voltage film 139 may have a thickness in a range from 5 nm to 1000 nm, inclusive, in a direction normal to the wall surface of the breakdown voltage trench 138. Preferably, the breakdown voltage film 139 has substantially the same thickness as the gate insulation film 127.

The breakdown voltage film 139 may be at least one of a silicon oxide film, a silicon nitride film, an aluminum oxide film, a zirconium oxide film, a hafnium oxide film, and a tantalum oxide film. Preferably, the breakdown voltage film 139 is formed from the same material as the gate insulation layer.

The breakdown voltage electrode 140 is embedded in the breakdown voltage trench 138 with the breakdown voltage film 139 interposed. More specifically, the breakdown voltage electrode 140, which is embedded in the recess space defined by the breakdown voltage film 139 near the bottom wall of the breakdown voltage trench 138, opposes the second semiconductor region 121B with the breakdown voltage film 139 interposed. The breakdown voltage electrode 140 is continuously integrated with the corresponding gate electrodes 128. The breakdown voltage electrode 140 extends across a boundary of the first semiconductor region 121A and the second semiconductor region 121B in a depth direction of the breakdown voltage trench 138.

The breakdown voltage electrode 140 may include at least one of a metal conductor and a non-metal conductor. The breakdown voltage electrode 140 may include at least one of tungsten, aluminum, copper, an aluminum alloy, a copper alloy, and a conductive polysilicon. Preferably, the breakdown voltage electrode 140 includes a non-metal conductor (conductive polysilicon). The conductive polysilicon may be a p-type polysilicon or an n-type polysilicon. Preferably, the conductive polysilicon is an n-type polysilicon.

The breakdown voltage insulator 141 is embedded in the breakdown voltage trench 138 at the open side of the breakdown voltage trench 138 and covers the breakdown voltage electrode 140. More specifically, the breakdown voltage insulator 141 is embedded in the open side recess defined by the breakdown voltage electrode 140. The breakdown voltage insulator 141 corresponds to a field insulator that reduces the electric field at the breakdown voltage trench 138. The area of the breakdown voltage insulator 141 facing the first semiconductor region 121A is greater than the area of the breakdown voltage electrode 140 facing the second semiconductor region 121B.

The breakdown voltage insulator 141 has a greater thickness than the breakdown voltage electrode 140 in the depth direction of the breakdown voltage trench 138. The breakdown voltage insulator 141 may be at least one of a silicon oxide film, a silicon nitride film, an aluminum oxide film, a zirconium oxide film, a hafnium oxide film, and a tantalum oxide film. Preferably, the breakdown voltage insulator 141 is formed by a silicon oxide film. Preferably, the breakdown voltage insulator 141 is formed from the same material as the breakdown voltage film 139. In this case, preferably, the breakdown voltage insulator 141 is formed by an insulative vapor deposition film and has a density that differs from that of the breakdown voltage film 139.

In each first mesa 131, the first source-drain region 107 is formed by the first semiconductor region 121A. A first contact region 142 is formed in an outer portion of the first source-drain region 107. The first contact region 142 has a higher n-type impurity concentration than the first semiconductor region 121A. The n-type impurity concentration of the first contact region 142 may be in a range from 1×10¹⁸ cm⁻³ to 1×10²¹ cm⁻³, inclusive (in this embodiment, approximately, 1×10¹⁹ cm⁻³).

Preferably, the first contact region 142 is formed in the central part of the corresponding first mesa 131 in plan view. The first contact region 142 is shorter than each first trench structure 123 in the second direction Y, and located inward from the two ends of each first trench structure 123. Each of the two ends of the first contact region 142 opposes the corresponding trench breakdown voltage structure 125 with part of the first semiconductor region 121A interposed in the second direction Y.

The first contact region 142 extends in a transverse direction (second direction Y) parallel to the first main surface 102 in a cross-sectional view. More specifically, the first contact region 142 is formed at a position located toward the first main surface 102 from the upper end of the gate electrode 128. The first contact region 142 opposes the embedded insulator 129 with part of the first semiconductor region 121A interposed in a transverse direction parallel to the first main surface 102. The first contact region 142 is separated from the upper end of the gate electrode 128 toward the first main surface 102, and does not face the gate electrode 128 in a transverse direction parallel to the first main surface 102. This reduces the electric field applied to the first trench structures 123.

The first contact region 142 may have a thickness in a range from 10 nm to 150 nm, inclusive (preferably, in a range from 50 nm to 100 nm, inclusive). Preferably, the first contact region 142 is spaced apart from the upper end of the gate electrode 128 in the thickness direction (normal direction Z) of the semiconductor chip 101 by a distance in a range from 0.1 μm to 2 μm, inclusive (preferably, in a range from 0.5 μm to 1.5 μm, inclusive).

In each second mesa 132, the second source-drain region 108 is formed by the first semiconductor region 121A. A second contact region 143 is formed in an outer portion of the second source-drain region 108. The second contact region 143 has a higher n-type impurity concentration than the first semiconductor region 121A. The n-type impurity concentration of the second contact region 143 may be in a range from 1×10¹⁸ cm⁻³ to 1×10²¹ cm⁻³, inclusive (in this embodiment, approximately 1×10¹⁹ cm⁻³).

Preferably, the second contact region 143 is formed in the central part of the second mesa 132 in plan view. The second contact region 143 is shorter than each first trench structure 123 in the second direction Y, and located inward from the two ends of each first trench structure 123. Each of the two ends of the second contact region 143 opposes the corresponding trench breakdown voltage structure 125 with part of the first semiconductor region 121A interposed in the second direction Y.

The second contact region 143 extends in a transverse direction (second direction Y) parallel to the first main surface 102 in a cross-sectional view. More specifically, the second contact region 143 is formed at a position located toward the first main surface 102 from the upper end of the gate electrode 128. The second contact region 143 opposes the embedded insulator 129 with part of the first semiconductor region 121A interposed in a transverse direction parallel to the first main surface 102. The second contact region 143 is separated from the upper end of the gate electrode 128 toward the first main surface 102, and does not face the gate electrode 128 in a transverse direction parallel to the first main surface 102. This reduces the electric field applied to the first trench structures 123.

The second contact region 143 has a thickness in a range from 10 nm to 150 nm, inclusive (preferably, in a range from 50 nm to 100 nm, inclusive). Preferably, the second contact region 143 is spaced apart from the upper end of the gate electrode 128 in the thickness direction (normal direction Z) of the semiconductor chip 101 by a distance in a range from 0.1 μm to 2 μm, inclusive (preferably, in a range from 0.5 μm to 1.5 μm, inclusive).

In each drift mesa 133, the draft region 109 is formed by the first semiconductor region 121A. In this embodiment, the draft region 109 is formed by the entire first semiconductor region 121A from the boundary 144A of the first semiconductor region 121A and the second semiconductor region 121B to the first main surface 102. The width of the draft region 109 in the first direction X is less than the width of each drift region 21 in the first embodiment. For example, the width of the drift region 21 is in a range from 0.2 μm to 10 μm, inclusive, whereas the width of the draft region 109 is in a range from 0.01 μm to 0.3 μm, inclusive.

The wiring region 111 is formed by the first semiconductor region 121A between adjacent cell regions 110. The wiring region 111 is continuously integrated with the ends of the draft region 109 in the second direction Y.

The wiring region 111 includes p-type projections 145 projecting selectively from the second semiconductor region 121B toward the first main surface 102 into the first semiconductor region 121A. Referring to FIG. 24, each projection 145 may extend upward in a parabolic manner from the boundary 144A of the first semiconductor region 121A and the second semiconductor region 121B, and include a peak in the vicinity of the first main surface 102. In this embodiment, the peak of the projection 145 is separated from the first main surface 102 toward the second main surface 103. Part of the wiring region 111 (draft region 109) may be formed between the peak of the projection 145 and the first main surface 102. Referring to FIG. 20, each projection 145 may be a strip extending in the first direction X. The projections 145 are formed in the wiring region 111, which is where there is no current path 185 (described later) in this embodiment. This allows the projections 145 to be formed in strips. Thus, a substrate potential contact may be formed anywhere in the wiring region 111. The projections 145 may be arranged at intervals in the first direction X.

Each projection 145 has a higher p-type impurity concentration than the second semiconductor region 121B (low-concentration region 121B2). The p-type impurity concentration of the projection 145 may be in a range from 1×10¹⁶ cm⁻³ to 1×10²² cm⁻³ (in this embodiment, approximately, 1×10¹⁹ cm⁻³).

A first impurity region 146 may be formed in the separating regions 137 and the wiring region 111. FIG. 20 does not show the first impurity region 146. The first impurity region 146 is formed proximate to the first main surface 102 in contact with the peak of each projection 145. The first impurity region 146 has a higher n-type impurity concentration than the first semiconductor region 121A. The n-type impurity concentration of the first impurity region 146 may be in a range from 1×10¹⁵ cm⁻³ to 1×10²⁰ cm⁻³ (in this embodiment, approximately 1×10¹⁸ cm⁻³).

The semiconductor device 1B includes a main surface insulation film 147 selectively covering the first main surface 102. The main surface insulation film 147 may be part of the insulation layer 9. The main surface insulation film 147 covers the first trench structures 123, the trench connecting structures 124, and the trench breakdown voltage structures 125 on the first main surface 102. In this embodiment, the main surface insulation film 147 entirely covers the first main surface 102 and is continuous with the first to fourth side surfaces 104A to 104D.

The main surface insulation film 147 may have a thickness in a range from 0.1 μm to 2 μm, inclusive. Preferably, the main surface insulation film 147 has a greater thickness than the gate insulation film 127. The main surface insulation film 147 may be at least one of a silicon oxide film, a silicon nitride film, an aluminum oxide film, a zirconium oxide film, a hafnium oxide film, and a tantalum oxide film. Preferably, the main surface insulation film 147 is formed by a silicon oxide film.

In this embodiment, the main surface insulation film 147 is formed from the same material as the embedded insulator 129 and the breakdown voltage insulator 141 and formed integrally with the embedded insulator 129 and the breakdown voltage insulator 141. More specifically, the main surface insulation film 147 enters the first trenches 126 and the breakdown voltage trenches 138 from above the first main surface 102 to form each embedded insulator 129 and each breakdown voltage insulator 141. In other words, the main surface insulation film 147 is formed on the first main surface 102 by an insulation film integrating the part of each embedded insulator 129 projecting out of the corresponding first trench 126 and the part of each breakdown voltage insulator 141 projecting out of the breakdown voltage trench 138.

The semiconductor device 1B includes first electrodes 148 electrically connected to the first semiconductor region 121A in the first mesas 131. In this embodiment, the first electrodes 148 each correspond to “the first lower contact.” The first electrodes 148 extend through the main surface insulation film 147 and are connected to the first mesas 131. More specifically, the first electrodes 148 are arranged in first connection openings 149, which are formed in the main surface insulation film 147.

The first electrodes 148 are formed from metal. In this embodiment, each first electrode 148 has a laminate structure including a first barrier film 150 and a first electrode body 151. The first barrier film 150 is formed along the wall of the corresponding first connection hole 149. The first barrier film 150 may be formed by a titanium-based metal film. The first barrier film 150 may have a monolayer structure or a laminate structure including one or both of a titanium film and a titanium nitride film.

The first electrode body 151 is embedded in the first connection opening 149 with the first barrier film 150 interposed and electrically connected to the corresponding first mesa 131 (first contact region 142) through the first barrier film 150. The first electrode body 151 may include at least one of tungsten, aluminum, copper, an aluminum alloy, and a copper alloy. In this embodiment, the first electrode body 151 includes tungsten. The first electrode 148 does not have to include the first barrier film 150 and may include only the first electrode body 151.

The semiconductor device 1B includes second electrodes 152 electrically connected to the first semiconductor region 121A in the second mesas 132. In this embodiment, the second electrodes 152 each correspond to “the second lower contact.” The second electrodes 152 extend through the main surface insulation film 147 and are connected to the second mesas 132. More specifically, the second electrodes 152 are arranged in second connection openings 153, which are formed in the main surface insulation film 147.

The second electrodes 152 are formed from metal. In this embodiment, each second electrode 152 has a laminate structure including a second barrier film 154 and a second electrode body 155. The second barrier film 154 is formed along the wall of the corresponding second connection opening 153. The second barrier film 154 may be formed by a titanium-based metal film. The second barrier film 154 may have a monolayer structure or a laminate structure including one or both of a titanium film and a titanium nitride film.

The second electrode body 155 is embedded in the second connection opening 153 with the second barrier film 154 interposed and electrically connected to the corresponding second mesa 132 (second contact region 143) through the second barrier film 154. The second electrode body 155 may include at least one of tungsten, aluminum, copper, an aluminum alloy, and a copper alloy. In this embodiment, the second electrode body 155 includes tungsten. The second electrode 152 does not have to include the second barrier film 154 and may include only the second electrode body 155.

The semiconductor device 1B includes second trench structures 156 formed in the first main surface 102 at the wiring regions 111.

In this embodiment, the second trench structures 156 are arranged at intervals in the first direction X. For example, when the projections 145 are arranged at intervals in the first direction X, the second trench structures 156 are each provided with one of the projections 145. Each second trench structure 156 is arranged facing the corresponding draft regions 109 in the second direction Y near the ends of the draft region 109. In this embodiment, the ends of two draft region 109 in the second direction Y are arranged adjacent to each second trench structure 156.

The second trench structures 156 extend to the projections 145. In this embodiment, the second trench structures 156 are shallower than the first trench structures 123. More specifically, the second trench structures 156 extend through the first impurity region 146 to the projections 145. Each second trench structure 156 has a bottom wall located in the projection 145.

The width of each of the second trench structures 156 may be greater than or equal to the width of each of the first trench structures 123 or less than each of the first trench structures 123. The second trench structures 156 may each have a depth in a range from 0.1 μm to 10 μm, inclusive (preferably, in a range from 0.2 μm to 0.5 μm, inclusive). Such a depth allows for the formation of a silicide layer 162 (described later) in the entire second trench structure 156.

Each second trench structure 156 includes a base trench 157 and a base electrode 158. In this embodiment, the base electrode 158 corresponds to “the first base contact 120.”

The base trench 157, which extends through the main surface insulation film 147, is formed in the first main surface 102 and defined by the wall surfaces (side walls and bottom wall) of the second trench structure 156. In this embodiment, the base trench 157 includes a base connection opening 159 formed in the main surface insulation film 147. More specifically, the base trench 157 extends through the main surface insulation film 147 and the first impurity region 146 to the projection 145. The first impurity region 146 and the projection 145 are exposed from the wall surfaces of the base trench 157.

The base trench 157 may be tapered so that its width narrows from the first main surface 102 toward the bottom side in a cross-sectional view. The base trench 157 may extend at a right angle from the first main surface 102. The base trench 157 may have curved bottom corners. The bottom wall of the base trench 157 may be entirely curved toward the second main surface 103.

The base electrode 158 is embedded in the base trench 157 without an insulation film. In the base trench 157, the base electrode 158 is mechanically and electrically connected to the first impurity region 146 and the projection 145, and mechanically connected to the main surface insulation film 147. In the base trench 157, the base electrode 158 includes a part extending from the first main surface 102 into the semiconductor chip 101 and a part extending from the first main surface 102 into the main surface insulation film 147. Thus, the base electrode 158 has an upper end projecting upward from the first main surface 102. Further, the upper end of the base electrode 158 projects upward from the upper end of the gate electrode 128 (upper end of each extension 130).

The base electrode 158 may include at least one of a metal conductor and a non-metal conductor. Preferably, the base electrode 158 and the gate electrode 128 are formed from different conductive materials. Preferably, the base electrode 158 includes a metal. In this embodiment, the base electrode 158 has a laminate structure including a base barrier film 160 and a base electrode body 161.

The base barrier film 160 is formed along the side walls and the bottom wall of the base trench 157, and covers the first impurity region 146, the projection 145, and the main surface insulation film 147 in the base trench 157. The base barrier film 160 defines a recess space in the base trench 157. The base barrier film 160 may be formed by a titanium-based metal film. The base barrier film 160 may have a monolayer structure or a laminate structure including one or both of a titanium film and a titanium nitride film. Preferably, the base barrier film 160 is formed from the same material as the first barrier film 150 and the second barrier film 154.

The base electrode body 161 is embedded in the base trench 157 with the base barrier film 160 interposed, and covers the first impurity region 146, the projection 145, and the main surface insulation film 147 with the base barrier film 160 interposed. The base electrode body 161 is electrically connected to the first impurity region 146 and the projection 145 by the base barrier film 160. The base electrode body 161 may include at least one of tungsten, aluminum, copper, an aluminum alloy, and a copper alloy. Preferably, the base electrode body 161 is formed from the same material as the first electrode body 151 and the second electrode body 155. In this embodiment, the base electrode body 161 includes tungsten. The base electrode 158 does not have to include the base barrier film 160, and may include only the base electrode body 161.

The silicide layer 162 is formed on the wall of the base trench 157. The silicide layer 162 is formed entirely on the side walls and bottom wall of the base trench 157 at the boundary of the semiconductor chip 101 and the base barrier film 160. The silicide layer 162 may extend vertically across the boundary of the first impurity region 146 and the projection 145 in the thickness direction of the semiconductor chip 101.

As long as the silicide layer 162 is formed entirely on the side walls and the bottom wall of the base trench 157, the wall smoothness of the base trench 157 can be improved thereby allowing for satisfactory contact between the base electrode body 161 and the base trench 157. This reduces the contact resistance of the base electrode body 161.

The semiconductor device 1B includes third electrodes 163 electrically connected to the first trench structures 123. The third electrodes 163 each correspond to “the first gate contact 117.” The third electrodes 163 extend through the main surface insulation film 147 and are mechanically and electrically connected to either one of or both of the first trench structures 123 (extensions 130) and the trench connecting structures 124 (connection electrode 136).

More specifically, the third electrodes 163 are arranged in third connection openings 164, which are formed in the main surface insulation film 147. In this embodiment, the third electrodes 163 are mechanically and electrically connected to the trench connection structures 124. That is, the third electrodes 163 are electrically connected to the first trench structures 123 by the trench connection structures 124.

In this embodiment, the third electrodes 163 are formed in correspondence with the trench connecting structures 124 in plan view. The third electrodes 163 may have any shape in plan view. The third electrodes 163 may be circular or quadrilateral in plan view.

The third electrodes 163 are formed from metal. In this embodiment, each third electrode 163 has a laminate structure including a third barrier film 165 and a third electrode body 166. The third barrier film 165 is formed along the wall of the corresponding third connection opening 164. The third barrier film 165 may be formed by a titanium-based metal film. The third barrier film 165 may have a monolayer structure or a laminate structure including one or both of a titanium film and a titanium nitride film. Preferably, the third barrier film 165 is formed from the same material as the first barrier film 150, the second barrier film 154, and the base barrier film 160.

The third electrode body 166 is embedded in the third connection opening 164 with the third barrier film 165 interposed and electrically connected to the extensions 130 (connection electrode 136) by the third barrier film 165. The third electrode body 166 may include at least one of tungsten, aluminum, copper, an aluminum alloy, and a copper alloy. Preferably, the third electrode body 166 is formed from the same material as the first electrode body 151. In this embodiment, the third electrode body 166 includes tungsten. The third electrode 163 does not have to include the third barrier film 165 and may include only the third electrode body 166.

The semiconductor device 1B includes a first interlayer insulation film 168 formed on the main surface insulation film 147. The first interlayer insulation film 168 may be part of the insulation layer 9. The first interlayer insulation film 168 may include at least one of silicon oxide and silicon nitride. The first interlayer insulation film 168 entirely covers the main surface insulation film 147 and is continuous with the first to fourth side surfaces 104A to 104D. The first interlayer insulation film 168 may include a flat surface extending along the first main surface 102. The flat surface of the first interlayer insulation film 168 may have polishing marks.

The first wiring layer 112 is formed on the first interlayer insulation film 168. The first wiring layer 112 may include at least one of titanium, tungsten, aluminum, copper, an aluminum alloy, a copper alloy, and a conductive polysilicon. The first wiring layer 112 may include at least one of a Cu film (Cu film having purity of 99% or greater), a pure Al film (Al film having purity of 99% or greater), an AlCu alloy film, an AlSi alloy film, and an AlSiCu alloy film.

As described above, the first wiring layer 112 includes the first gate wiring layer 113 and the first base wiring layer 114. Referring to FIG. 21, one of the two first gate wiring layers 113 (gate branching portions 116) extending in the first direction X in the wiring region 111 is connected to the connection electrodes 136 of one of the cell regions 110 in the wiring region 111. The other one of the two first gate wiring layers 113 (gate branching portions 116) is connected to the third electrodes 163 (connection electrodes 136) of the other one of the cell regions 110 in the wiring region 111. Further, in this embodiment, the first gate wiring layer 113 covers the trench connecting structures 124 in plan view but does not cover the trench breakdown voltage structures 125.

The first base wiring layer 114 extends through the wiring region 111 in the first direction X and is connected to the base electrodes 158 (first base contacts 120). In this embodiment, as shown in FIG. 19, the first base contacts 120 are arranged below the base peripheral portion 118 and the base branching portions 119, and are connected to the base peripheral portion 118 and the base branching portions 119.

The first wiring layer 112 further includes a first lower wiring layer 169 and a second lower wiring layer 170. Referring to FIG. 22, the first lower wiring layer 169 extends through the first interlayer insulation film 168 and is connected to the first electrodes 148. The second lower wiring layer 170 extends through the first interlayer insulation film 168 and is connected to the second electrodes 152.

The semiconductor device 1B includes a second interlayer insulation film 171 formed on the first interlayer insulation film 168 to cover the first wiring layer 112. The second interlayer insulation film 171 may be part of the insulation layer 9. The second interlayer insulation film 171 may include at least one of silicon oxide and silicon nitride. The second interlayer insulation film 171 entirely covers the first interlayer insulation film 168 and is continuous with the first to fourth side surfaces 104A to 104D. The second interlayer insulation film 171 may include a flat surface extending along the first main surface 102. The flat surface of the second interlayer insulation film 171 may have polishing marks.

A second wiring layer 172 is formed on the second interlayer insulation film 171. The second wiring layer 172 may include at least one of titanium, tungsten, aluminum, copper, an aluminum alloy, a copper alloy, and a conductive polysilicon. The second wiring layer 172 may include at least one of a Cu film (Cu film having purity of 99% or greater), a pure Al film (Al film having purity of 99% or greater), an AlCu alloy film, an AlSi alloy film, and an AlSiCu alloy film.

The second wiring layer 172 includes a first upper wiring layer 173, a second upper wiring layer 174, a second gate wiring layer (not shown), and a second base wiring layer (not shown). The first upper wiring layer 173 extends through the second interlayer insulation film 171 and is connected to the first lower wiring layer 169. The second upper wiring layer 174 extends through the second interlayer insulation film 171 and is connected to the second lower wiring layer 170. The second gate wiring layer extends through the second interlayer insulation film 171 and is connected to the first gate wiring layer 113. The second base wiring layer extends through the second interlayer insulation film 171 and is connected to the first base wiring layer 114.

The semiconductor device 1B includes an uppermost insulation film 175 formed on the second interlayer insulation film 171. The uppermost insulation film 175 may be part of the insulation layer 9. The uppermost insulation film 175 may be referred to as “the passivation layer.” The uppermost insulation film 175 may have a laminate structure in which an inorganic insulation film (inorganic film) and an organic insulation film (organic film) are laminated in order from the second interlayer insulation film 171. The uppermost insulation film 175 may have a monolayer structure formed by an inorganic insulation film (inorganic film) or an organic insulation film (organic film). Preferably, the inorganic insulation film and the second interlayer insulation film 171 are formed from different insulation materials. The inorganic insulation film may be, for example, a silicon nitride film. The organic insulation film may be formed from a photosensitive resin. The organic insulation film may include at least one of a polyimide film, a polyamide film, and a polybenzoxazole film.

In the same manner as the first embodiment, the external terminals 4 to 7 are formed on the uppermost insulation film 175.

The semiconductor device 1B includes a second main surface protection film 176 that covers the second main surface 103 of the semiconductor chip 101. In this embodiment, the second main surface protection film 176 entirely covers the second main surface 103 and also covers the first to fourth side surfaces 104A to 104D. The second main surface protection film 176 may have a monolayer structure formed by an inorganic insulation film (inorganic film) or an organic insulation film (organic film). The inorganic insulation film may be, for example, a silicon nitride film. The organic insulation film may be formed from a photosensitive resin. The organic insulation film may include at least one of a polyimide film, a polyamide film, and a polybenzoxazole film.

Referring to FIG. 22, the semiconductor device 1B includes first pn junctions 177 and second pn junctions 178 formed inside the semiconductor chip 101. Each first pn junction 177 is formed in one of the first mesas 131 at the boundary 144A between the first semiconductor region 121A and the second semiconductor region 121B. This forms a first body diode D1 including the second semiconductor region 121B as an anode region and the first semiconductor region 46A as a cathode region in the first mesa 131.

Each second pn junction 178 is formed in one of the second mesas 132 at the boundary 144A between the first semiconductor region 121A and the second semiconductor region 121B. This forms a second body diode D2 including the second semiconductor region 121B as an anode region and the first semiconductor region 121A as a cathode region in the second mesa 132. The anode of the second body diode D2 (second pn junction 178) is electrically connected to the anode of the first body diode D1 (first pn junction 177) by the second semiconductor region 121B.

### Operation of Semiconductor Device 1B

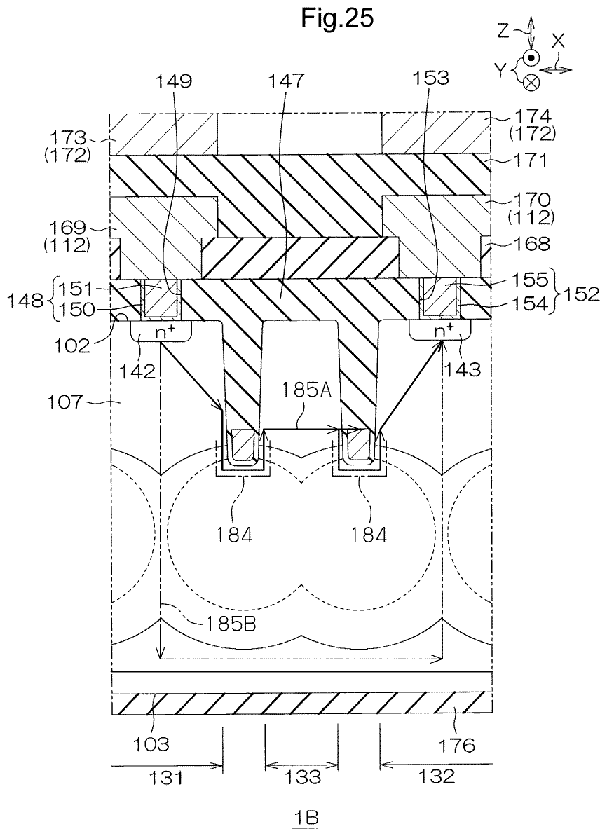

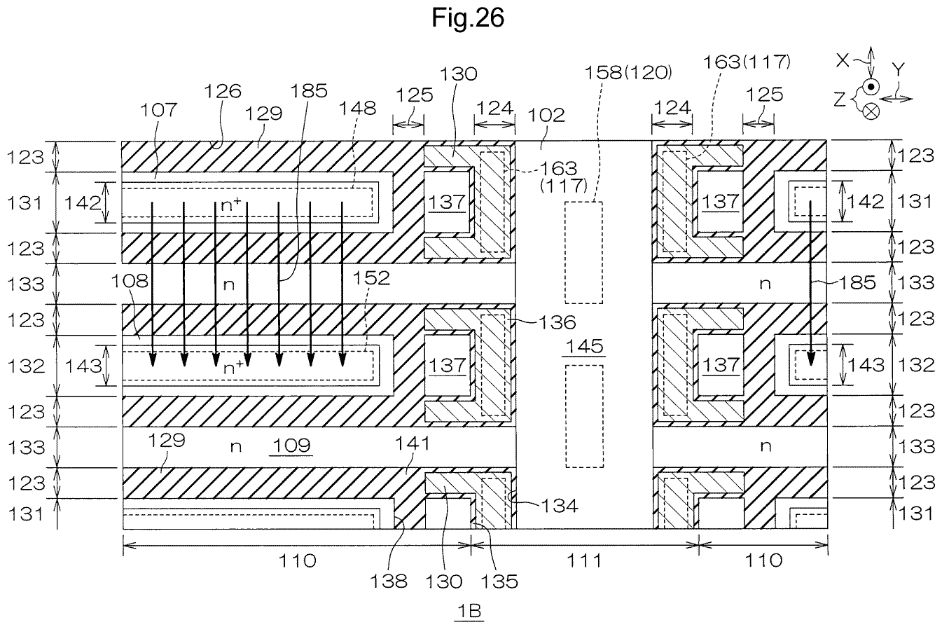

FIG. 25 is a cross-sectional view illustrating the current paths 185 of the semiconductor device 1B in accordance with the second embodiment of the present disclosure. FIG. 26 is a plan view illustrating the current paths 185 of the semiconductor device 1B in accordance with the second embodiment of the present disclosure. The current paths 185 include a first current path 185A and a second current path 185B.

The semiconductor device 1B has a MISFET structure of a trench gate-lateral type. In the MISFET structure, gate potential is applied to the first trench structures 123 (gate electrodes 128), drain potential is applied to the first mesas 131, and source potential is applied to the second mesas 132. This forms, in the second semiconductor region 121B, the channel 184 in the region under each first trench structure 123, and the first current path 185A in a lateral direction connecting the first electrodes 148 (first mesas 131) and the second electrodes 152 (second mesas 132).

As shown in FIG. 25, current flows through the first current path 185A in order from the first mesas 131 (first semiconductor region 121A), the second semiconductor region 121B (high-concentration region 121B1), the drift mesas 133 (first semiconductor region 121A), the second semiconductor region 121B (high-concentration region 121B1), and the second mesas 132 (first semiconductor region 121A).

When current of a certain amount or greater flows through the first current path 185A, the second current path 185B is additionally formed in the lateral direction connecting the first electrodes 148 (first mesas 131) and the second electrodes 152 (second mesas 132). Current flows through the second current path 185B in order from the first mesas 131 (first semiconductor region 121A), the second semiconductor region 121B (low-concentration region 121B2), the third semiconductor region 121C, the second semiconductor region 121B (low-concentration region 121B2), and the second mesas 132 (first semiconductor region 121A). The current paths 185 include the second current path 185B in addition to the first current path 185A. This increases the current flowing through the current path 185. As a result, the on resistance can be decreased.

In the semiconductor device 1B, as shown in FIG. 26, the base electrode 158, which fixes the potential (substrate potential) at the second semiconductor region 121B, is formed in the wiring region 111, which is separated in the second direction Y from the draft region 109 where the current path 185 is formed. The base electrodes 158 are not formed in the draft regions 109. This forms the current paths 185 connecting the first electrodes 148 and the second electrodes 152 over the shortest distance in the entire draft region 109. Thus, the wiring region 111 for fixing the substrate potential is arranged separately from the draft region 109 for the current path 185. This decreases the on resistance.

Further, the draft region 109 does not need space for the base electrode 158 thereby allowing the draft region 109 to be narrowed in the first direction X. Thus, the resistance of each draft region 109 can be decreased, and the number of cells laid out in a single cell region 110 can be increased. As a result, the on resistance can be decreased.

As shown in FIG. 24, the projection 145 extends toward the first main surface 102. This raises the point where the second trench structure 156 contacts the second semiconductor region 121B toward the first main surface 102 from the boundary 144A of the first semiconductor region 121A and the second semiconductor region 121B. Thus, the second trench structure 156 does not have to extend to the boundary 144A, and the substrate potential may be fixed with the relatively shallow second trench structure 156. The shallow base trench 157 ensures contact for the substrate potential with a simple structure.

Referring to FIG. 24, for example, when the second trench structure 156 is deep and further extends from the boundary 144A toward the second main surface 103, there may be parts where the silicide layer 162 is not formed on the walls of the base trench 157. More specifically, the silicide layer 162 may be locally formed on the bottom wall and the upper end of each side wall of the base trench 157 but the silicide layer 162 may not be formed on other wall parts of the base trench 75. In this respect, in the structure shown in FIG. 24, the base trench 157 is shallow. This allows the silicide layer 162 to be formed entirely on the second trench structure 156. Thus, the base trench 157 has smooth wall surfaces that allow for satisfactory contact between the base electrode body 161 and the base trench 157. This reduces the contact resistance of the base electrode body 161.

The wiring region 111 for fixing the substrate potential is formed in the active region 105. Thus, there is no need for the peripheral region 106 to include a peripheral structure for fixing the substantial potential. This allows the area of the peripheral region 106 to be decreased, and the area of the active region 105 to be increased. As a result, the current characteristics of the semiconductor device 1A can be improved. For example, in the semiconductor device 1A, the occupancy rate of the active region 105 in the first main surface 102 may be in a range of 10% to 99.9%, inclusive.

Further, the trench breakdown voltage structure 125 separates the end part of the corresponding first source-drain region 107 or the corresponding second source-drain region 108 in the second direction Y from the remaining part. The trench breakdown voltage structures 125 are located between the first source-drain regions 107 and the trench connecting structures 124 and between the second source-drain regions 108 and the trench connecting structures 124. This increases the breakdown voltage in the lateral direction that is parallel to the first main surface 102 of the semiconductor device 1B.

### Advantages of the Semiconductor Device 1B

The semiconductor device 1B also has advantages (1-1) and (1-2) of the first embodiment.

### Modified Examples of the Semiconductor Device 1B

Modified examples of the semiconductor device 1B will now be described.

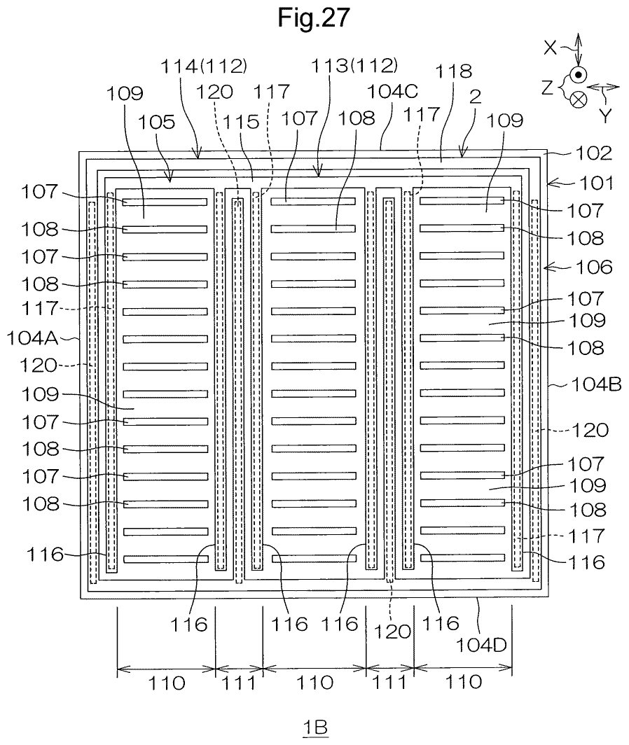

In FIG. 19, the first gate contacts 117 are arranged at intervals in the first direction X, and the first base contacts 120 are arranged at intervals in the first direction X. In contrast, as shown in FIG. 27, a single first gate contact 117 and a single first base contact 120 may extend across the vicinity of the end of each first source-drain region 107 and each second source-drain region 108.

The projections 145 may extend from the second semiconductor region 121B through the first semiconductor region 121A to the first main surface 102. The peak of each projection 145 may be exposed from the first main surface 102 in the wiring region 111. In this case, the base electrode 158 does not have to be formed as the second trench structure 156. The base electrode 158 is embedded in the base connection opening 159 and has a bottom at the first main surface 102. This connects the base electrode 158 to the projection 145 at the first main surface 102. This structure allows the step of forming the second trench structures 156 to be omitted. Thus, the manufacturing process can be simplified. Further, the material used can be reduced, and the cost of manufacturing can be decreased.

In the same manner as the semiconductor device 1A shown in FIG. 17, the second trench structures 156 may be deeper than the first trench structures 123. More specifically, the base trench 157, which is deeper than the first trench 126, may extend across the boundary 144A to the second semiconductor region 121B. This allows the step of forming the projection 145 to be omitted. Thus, the manufacturing process can be simplified. Further, the material used can be reduced, and the cost of manufacturing can be decreased.

In the same manner as the semiconductor device 1A shown in FIG. 18, the second main surface protection film 176 may be omitted from the second main surface 103 of the semiconductor chip 101, and the second main surface 103 may be an exposed surface.

### Modified Examples Common to the Semiconductor Devices 1A and 1B

The above embodiments may be modified as described below.

In the examples of each of the above embodiments, “the first conductivity type” refers to “the n-type,” and “the second conductivity type” refers to “the p-type.” Instead, “the first conductivity type” may be “the p-type”, and “the second conductivity type” may be the “n-type.” Such a configuration may be constructed by replacing “n-type regions” with “p-type regions” and replacing “n-type regions” with “p-type regions” in the above description and accompanying drawings.

Preferably, in each of the above embodiments, when the semiconductor chips 8 and 101 include SiC monocrystals, the SiC monocrystals of the semiconductor chips 8 and 101 are hexagonal crystals. SiC monocrystals of hexagonal polytypes, which are classified based on their atomic stacking sequence, include 2H (Hexagonal)-SiC, 4H-SiC, and 6H-SiC monocrystals. Preferably, among these polytypes, the semiconductor chips 8 and 101 include 4H-SiC monocrystals.

In this case, preferably, the first main surfaces 10 and 102 correspond to the silicon face, or (0001) face, of each SiC monocrystal, and the second main surfaces 11 and 103 correspond to the carbon face, or (000-1) face, of each SiC monocrystal. Instead, the first main surfaces 10 and 102 may correspond to the carbon face, and the second main surfaces 11 and 103 may correspond to the silicon face. The (0001) face and the (000-1) face of each SiC monocrystal are each referred to as the C-face.

The first main surfaces 10 and 102 may have an off angle inclined at a predetermined angle in a predetermined off direction with respect to the C-face of the SiC monocrystal. The off direction may be the a-axis direction, or [11-20] direction, of the SiC monocrystal. The off angle may be in a range from 0° to 5.0°, inclusive. In this case, the first direction X is the m-axis direction of the SiC monocrystal, and the second direction Y is the a-axis direction of the SiC monocrystal. Instead, the first direction X may be the a-axis direction of the SiC monocrystal, and the second direction Y may be the m-axis direction of the SiC monocrystal.

### CLAUSES

Technical concepts that can be understood from the present disclosure will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### Clause 1

A semiconductor device (1A, 1B), including:
a semiconductor chip (8, 101) including a first main surface (10, 102) and a second main surface (11, 103) at an opposite side of the first main surface (10, 102);
a first semiconductor region (46A, 121A) of a first conductivity type that is formed in the semiconductor chip (8, 101) near the first main surface (10, 102);
a second semiconductor region (46B, 121B) of a second conductivity type that is formed closer to the second main surface (11, 103) than the first semiconductor region (46A, 121A) is;
a trench structure (17, 123) including a trench (48, 126) extending from the first main surface (10, 102) through the first semiconductor region (46A, 121A) and partitioning the first semiconductor region (46A, 121A) in cross section into a first region at one side and a second region at another side, a control insulation film (49, 127) covering a wall of the trench (48, 126), and a control electrode (50, 128) embedded in the trench (48, 126) with the control insulation film (49, 127) interposed and controlling a channel (96, 184) that electrically connects the first region and the second region in a transverse direction extending parallel to the first main surface (10, 102) in the second semiconductor region (46B, 121B); and
a third semiconductor region (46C, 121C) of the first conductivity type that is formed closer to the second main surface (11, 103) than the second semiconductor region (46B, 121B), where the third semiconductor region (46C, 121C) and the trench structure (17, 123) sandwich the second semiconductor region (46B, 121B).

### Clause 2

The semiconductor device (1A, 1B) according to clause 1, where the second semiconductor region (46B, 121B) immediately below a distal end of the trench (48, 126) has a thickness in a range from 0.01 μm to 10 μm, inclusive.

### Clause 3

The semiconductor device (1A, 1B) according to clause 1 or 2, where:
the first semiconductor region (46A, 121A) includes
   a first contact region (22, 142) electrically connected to a first electrode (65, 148) in the first region, and
   a second contact region (24, 143) electrically connected to a second electrode (69, 152) in the second region; and
the second semiconductor region (46B, 121B) immediately below at least one of the first contact region (22, 142) and the second contact region (24, 143) has a thickness in a range from 0.01 μm to 10 μm, inclusive.

### Clause 4

The semiconductor device (1A, 1B) in accordance with any one of clauses 1 to 3, where:
the first semiconductor region (46A, 121A) includes
   a first contact region (22, 142) electrically connected to a first electrode (65, 148) in the first region, and
   a second contact region (24, 143) electrically connected to a second electrode (69, 152) in the second region; and
the second semiconductor region (46B, 121B) immediately below at least one of the first contact region (22, 142) and the second contact region (24, 143) is thinner than the second semiconductor region (46B, 121B) immediately below a distal end of the trench (48, 126).

### Clause 5

The semiconductor device (1A, 1B) according to any one of clauses 1 to 4, where the third semiconductor region (46C, 121C) immediately below a distal end of the trench (48, 126) has a thickness of 0.001 μm or greater.

### Clause 6

The semiconductor device (1A, 1B) according to any one of clauses 1 to 5, where the third semiconductor region (46C, 121C) has a lower first conductivity type impurity concentration than the first semiconductor region (46A, 121A).

### Clause 7

The semiconductor device (1A, 1B) according to any one of clauses 1 to 6, where the second semiconductor region (46B, 121B) electrically insulates the first semiconductor region (46A, 121A) and the third semiconductor region (46C, 121C).

### Clause 8

The semiconductor device (1A, 1B) according to any one of clauses 1 to 7, further including:
a drift region (21, 109) sandwiched between the trench structure (17, 123) and a further trench structure (17, 123), where
   the first region includes a first source-drain region (19, 107) opposing the drift region (21, 109) with one of the trench structures (17, 123) interposed, and
   the second region includes a second source-drain region (20, 108) opposing the drift region (21, 109) with one of the trench structures (17, 123) interposed;
a first source-drain electrode (65, 148) electrically connected to the first source-drain region (19, 107); and
a second source-drain electrode (69, 152) electrically connected to the second source-drain region (20, 108).

### Clause 9

The semiconductor device (1A, 1B) according to clause 8, where:
the drift region (21, 109), the first source-drain region (19, 107), and the second source-drain region (20, 108) are arranged sandwiching the trench structures (17, 123) in a first direction; and
the drift region (21, 109) is shorter in length in the first direction than the first source-drain region (19, 107) and shorter in length in the first direction than the second source-drain region (20, 108).

### Clause 10

A method for manufacturing a semiconductor device (1A, 1B), the method including:
in a semiconductor chip (91) including a first main surface (92), a second main surface (93) at an opposite side of the first main surface (92), and a first conductivity type region (91B) near the first main surface (92), forming a trench (48, 126) in the first conductivity type region (91B) from the first main surface (92);
implanting impurities of a second conductivity type into the first conductivity type region (91B) through the trench (48, 126) to form a second semiconductor region (46B, 121B) of the second conductivity type that separates the first conductivity type region (91B) into a first semiconductor region (46A, 121A) of a first conductivity type located near the first main surface (92) and a third semiconductor region (46C, 121C) of the first conductivity type located near the second main surface (93);
forming a control insulation film (49, 127) covering a wall of the trench (48, 126); and
forming a control electrode (50, 128) embedded in the trench (48, 126) with the control insulation film (49, 127) interposed.

1. A semiconductor device, comprising:
a semiconductor chip including a first main surface and a second main surface at an opposite side of the first main surface;
a first semiconductor region of a first conductivity type that is formed in the semiconductor chip near the first main surface;
a second semiconductor region of a second conductivity type that is formed closer to the second main surface than the first semiconductor region is;
a trench structure including a trench extending from the first main surface through the first semiconductor region and partitioning the first semiconductor region in cross section into a first region at one side and a second region at another side, a control insulation film covering a wall of the trench, and a control electrode embedded in the trench with the control insulation film interposed and controlling a channel that electrically connects the first region and the second region in a transverse direction extending parallel to the first main surface in the second semiconductor region; and
a third semiconductor region of the first conductivity type that is formed closer to the second main surface than the second semiconductor region, wherein the third semiconductor region and the trench structure sandwich the second semiconductor region.

2. The semiconductor device according to claim 1, wherein the second semiconductor region immediately below a distal end of the trench has a thickness in a range from 0.01 μm to 10 μm, inclusive.

3. The semiconductor device according to claim 1, wherein:
the first semiconductor region includes
a first contact region electrically connected to a first electrode in the first region, and
a second contact region electrically connected to a second electrode in the second region; and
the second semiconductor region immediately below at least one of the first contact region and the second contact region has a thickness in a range from 0.01 μm to 10 μm, inclusive.

4. The semiconductor device according to claim 1, wherein:
the first semiconductor region includes
a first contact region electrically connected to a first electrode in the first region, and
a second contact region electrically connected to a second electrode in the second region; and
the second semiconductor region immediately below at least one of the first contact region and the second contact region is thinner than the second semiconductor region immediately below a distal end of the trench.

5. The semiconductor device according to claim 1, wherein the third semiconductor region immediately below a distal end of the trench has a thickness of 0.001 μm or greater.

6. The semiconductor device according to claim 1, wherein the third semiconductor region has a lower first conductivity type impurity concentration than the first semiconductor region.

7. The semiconductor device according to claim 1, wherein the second semiconductor region electrically insulates the first semiconductor region and the third semiconductor region.

8. The semiconductor device according to claim 1, further comprising:
a drift region sandwiched between the trench structure and a further trench structure, wherein
the first region includes a first source-drain region opposing the drift region with one of the trench structures interposed, and
the second region includes a second source-drain region opposing the drift region with one of the trench structures interposed;
a first source-drain electrode electrically connected to the first source-drain region; and
a second source-drain electrode electrically connected to the second source-drain region.

9. The semiconductor device according to claim 8, wherein:
the drift region, the first source-drain region, and the second source-drain region are arranged sandwiching the trench structures in a first direction; and
the drift region is shorter in length in the first direction than the first source-drain region and shorter in length in the first direction than the second source-drain region.

10. A method for manufacturing a semiconductor device, the method comprising:
in a semiconductor chip including a first main surface, a second main surface at an opposite side of the first main surface, and a first conductivity type region near the first main surface, forming a trench in the first conductivity type region from the first main surface;
implanting impurities of a second conductivity type into the first conductivity type region through the trench to form a second semiconductor region of the second conductivity type that separates the first conductivity type region into a first semiconductor region of a first conductivity type located near the first main surface and a third semiconductor region of the first conductivity type located near the second main surface;
forming a control insulation film covering a wall of the trench; and
forming a control electrode embedded in the trench with the control insulation film interposed.
